(19) United States
(12) Patent Application Publication
(10) Pub. No.: US 2026/0128686 A1
(43) Pub. Date: May 7, 2026

(54) CORE-SHELL SUPRAMOLECULAR HYDROGEL FIBER MOISTURE ELECTRICAL GENERATORS ENABLED BY SYNERGETIC COMPLEX COACERVATION AND BUILT-IN POTENTIAL

(71) Applicant: UIF (University Industry Foundation), Yonsei University, Seoul (KR)

(72) Inventors: Cheolmin PARK, Seoul (KR); Guangtao ZAN, Seoul (KR); Shengyou LI, Seoul (KR); Kaiying ZHAO, Seoul (KR); Gwanho KIM, Seoul (KR)

(73) Assignee: UIF (University Industry Foundation), Yonsei University, Seoul (KR)

(21) Appl. No.: 19/368,349

(22) Filed: Oct. 24, 2025

(30) Foreign Application Priority Data
Nov. 5, 2024 (KR) 10-2024-0154951

(51) Int. Cl. H02N 1/06

(52) U.S. Cl. CPC H02N 1/06

(57) ABSTRACT

A moisture electricity generator (MEG) and a method for manufacturing the same are disclosed. The moisture electricity generator comprises a core that includes a conductive polymer; and a shell that at least partially surrounds the core and comprising a complex coacervate with ions. A potential gradient may arise from the difference in moisture or wettability between the core and the shell.

### CROSS-REFERENCE TO RELATED APPLICATION

This application claims priority from Korean Patent Application No. 10-2024-0154951 filed on Nov. 5, 2024 in the Korean Intellectual Property Office, and all the benefits accruing therefrom under 35 U.S.C. 119, the contents of which in its entirety are herein incorporated by reference.

### BACKGROUND

### Field

The present invention relates to a core-shell supramolecular hydrogel fiber moisture electricity generator through interacting complex coacervation and built-in potential. Specifically, the present invention pertains to a moisture electricity generator, a method for manufacturing the same, and the generator itself.

### Description of Related Art

The development of self-powered flexible wearable electronic devices has garnered significant attention for the advancement of human-machine interface technology. Accordingly, various sophisticated electric generators capable of harvesting ambient energy, such as friction-based/piezoelectric nanogenerators, thermoelectric generators, solar cells, and moisture electricity generators (MEGs), have been devised. Among these, MEGs have the potential to be suitable for self-powered electronic devices, as they operate based on widely available moisture and can meet high harvesting performance, excellent mechanical resilience, breathability, and biocompatibility similar to other alternatives. Although high-performance MEGs have been extensively researched by exploring new materials with optimized device structures, such as graphene oxide, carbon dots, hydrogels, proteins, aerogels, and polymer electrolytes, energy harvesting performance still falls short, necessitating the development of new material strategies for performance enhancement.

In the prior art, it has been revealed that the relatively low current density generated in the MEG is due to a limited number of dissociated mobile ions in the energy-generating material, as well as the long transport pathways and slow diffusion rates associated with them, which result in low power density. To address this fundamental issue of the MEG, the inventor considered that a complex coacervation process involving phase separation of two oppositely charged polymer electrolytes, one of the most effective microencapsulation technologies widely used in pharmaceuticals, food, agriculture, and the textile industry, would be promising. This is because a large number of additional mobile ions can be easily generated during the complex coacervation process. Furthermore, the phase separation associated with the dense coacervate increases the free volume within the system, enabling rapid diffusion of ions. To further promote the diffusion of ions, a fiber-based MEG with a core-shell structure comprising a mechanically flexible electrode core and coacervate shell is proposed, which provides durability against various mechanical deformations such as bending, folding, rolling, and twisting.

### SUMMARY

The present invention proposes a complex coacervation and built-in potential strategy for developing a high-performance fiber-based moisture electricity generator (MEG) with mechanical flexibility in a core-shell structure. The core-shell fiber-type MEG consists of a poly(3,4-ethylenedioxythiophene) (PEDOT) core and a shell made of a polydiallyldimethylammonium chloride (PDDA) and sodium alginate (NaAlg) complex coacervate, which is wrapped in a copper foil-based peripheral electrode (FIG. 1A). During the entropy-driven complex coacervation of PDDA and NaAlg with opposite charges in the fiber shell, a large amount of mobile counterions is additionally released, and due to the newly created free volume, the mobile ions rapidly and easily diffuse to the copper electrode. Furthermore, the PEDOT core with a negative surface potential (built-in potential) facilitates charge separation and enables ion diffusion in the electric field direction, providing a highly flexible high-performance fiber-based MEG. Self-powered information transmission was achieved based on an interactive MEG corresponding to finger movements. Moreover, a long-lasting operational artificial synaptic memristor mimicking autonomous human synapses was constructed by connecting the fiber-based MEG to a synapse.

The task that the present invention aims to solve is to improve the efficiency of moisture-based electricity generators and to maintain stable power output in various environments. Through this, the application range of self-powered devices can be expanded, providing users with an enhanced energy harvesting solution. Additionally, this technology may also have potential applications in innovative fields such as wearable devices and artificial synapses.

In one aspect, the invention provides a moisture electricity generator (MEG) comprising a core that includes a conductive polymer; and a shell that at least partially surrounds the core and includes a complex coacervate containing ions; wherein a potential gradient is generated from the difference in moisture or wettability between the core and the shell.

In one embodiment, the conductive polymer may comprise PEDOT (poly(3,4-ethylenedioxythiophene)).

In one embodiment, the complex coacervate may comprise polydiallyldimethylammonium chloride (PDDA) and sodium alginate (NaAlg).

In one embodiment, the moisture electricity generator may further include a peripheral electrode formed on the shell.

In one embodiment, the moisture electricity generator can generate electrical energy from the potential gradient between the core and the peripheral electrode.

In one embodiment, the peripheral electrode may comprise a metal.

In one embodiment, the core and the shell may be formed in a fiber form.

In one embodiment, the moisture electricity generator may further comprise a peripheral electrode formed on the shell.

In one embodiment, the peripheral electrode may be formed of a metal wire that spirally wound around the fiber-shaped core and shell.

In one embodiment, the moisture electricity generator can generate electrical energy from the potential gradient between the core and the peripheral electrode.

In another aspect, the present invention provides a method for manufacturing a moisture electricity generator (MEG), the method comprising forming a shell that at least partially surrounds the outer surface of a core comprising a conductive polymer, the shell comprising a complex coacervate containing ions.

In one embodiment, the conductive polymer may be prepared to include PEDOT (poly(3,4-ethylenedioxythiophene)).

In one embodiment, the complex coacervate may be prepared to include polydiallyldimethylammonium chloride (PDDA) and sodium alginate (NaAlg).

In one embodiment, a peripheral electrode forming step of forming a peripheral electrode on the shell may be further included.

In one embodiment, the peripheral electrode may be prepared to include a metal.

In one embodiment, the core is prepared in a fiber form, and the shell can be formed in a fiber form that wrap around the core.

In one embodiment, a peripheral electrode forming step for forming a peripheral electrode on the shell may be further included.

In one embodiment, the peripheral electrode may be prepared to include a metal.

In one embodiment, the core is prepared in the form of a fiber, and the shell can be formed in the form of a fiber that surrounds the core.

In one embodiment, a peripheral electrode forming step for forming a peripheral electrode on the shell may further be included.

In one embodiment, the peripheral electrode may be formed by spirally winding a metal wire around the fiber-shaped core and shell.

Another aspect of the present invention provides an electricity generator connected to a self-powered sensor or an artificial synapse device using the moisture electricity generator according to the embodiment of the present invention.

Moisture electricity generators (MEGs) have been extensively studied; however, demonstrations of high-performance flexible variants have been rare. The present invention proposes a novel complex coacervation and inherent potential strategy for developing a high-performance uniaxial MEG. This device features a gel shell composed of a poly(3,4-ethylenedioxythiophene) (PEDOT) core with a built-in charge potential and a coacervate of polydiallyldimethylammonium chloride (PDDA) and sodium alginate (NaAlg). The complex coacervation of the two oppositely charged polymer electrolytes generates additional mobile charge carriers and free volume within the device, while the surface charge of the PEDOT core significantly accelerates the diffusion of the charge carriers. As a result, this uniaxial fiber-based MEG demonstrates groundbreaking performance, achieving an output voltage of up to 0.8V, a maximum current density of 1.05 mA/cm², and a power density of 184 W/cm² at 20% relative humidity. Furthermore, the device of the present invention ensures mechanical robustness without performance degradation even after 100,000 folding cycles, making it suitable for self-powered human interaction sensors and synapses. Notably, the inventors have constructed the first MEG-synapse self-powered device, successfully operating a fiber-based MEG to mimic autonomous human synapses connected to fiber neurons. Overall, the present invention pioneers new design strategies and application scenarios for high-performance MEGs.

The effects of the present invention can enhance the performance of the moisture electricity generator and help increase its applicability in various environments. Through this, users can efficiently harvest energy and maximize the practicality of self-powered devices. Additionally, this technology has the potential to ensure the stability of power generation and contribute to fields such as wearable devices and artificial synapses.

### BRIEF DESCRIPTION OF DRAWINGS

FIG. 1A illustrates the design of a fiber-based moisture electricity generator (MEG), depicting the synergy strategy of complex coacervation and built-in potential.

FIG. 1B shows the output voltage of the fiber-based moisture electricity generator (MEG).

FIG. 1C shows the current density of the fiber-based moisture electricity generator (MEG).

FIG. 1D shows the voltage and current density of the fiber-based MEG according to the change in electrical resistance.

FIG. 1E shows a corresponding graph of the power density of the fiber-based MEG at 20% relative humidity.

FIG. 1F compares the performance of the fiber-based MEG with the performance of previously reported MEGs.

FIG. 1G shows a radar chart comparing the characteristics of representative moisture electricity generators (MEGs).

FIG. 2A illustrates a schematic of the preparation process of PEDOT@PDDA/NaAlg core-shell fibers.

FIG. 2B shows a SEM image of the PEDOT ribbon.

FIG. 2C shows the wrinkling of the PEDOT ribbon.

FIG. 2D illustrates the twisting of the PEDOT ribbon.

FIG. 2E shows the hydrophilicity of the PEDOT ribbon.

FIG. 2F illustrates the repeated folding of the PEDOT ribbon.

FIG. 2G shows a cross-section of the PEDOT@P5N20 core-shell fiber.

FIG. 2H shows the EDS map of the cross-section of the PEDOT@P5N20 core-shell fiber.

FIG. 2I shows the FT-IR spectra of PEDOT core-based fibers and PDDA films.

FIG. 2J shows the high-resolution C is XPS profile of the PEDOT core-based fiber and PDDA film.

FIG. 2K shows the high-resolution N is XPS profile of the PEDOT core-based fiber and PDDA film.

FIG. 3A shows the characteristics of fiber-type MEGs according to different PDDA/NaAlg ratios at 20% relative humidity.

FIG. 3B shows the characteristics of PEDOT@P5N20 fibers gelled with different concentrations of CaCl₂).

FIG. 3C shows the characteristics of PEDOT@P5N20 fibers that have undergone different gelation cycles.

FIG. 3D shows the properties of PEDOT@P5N20 fibers at different temperatures.

FIG. 3E shows the properties of PEDOT@P5N20 fibers at different relative humidity levels.

FIG. 3F shows the characteristics of PEDOT@P5N20 fibers of different lengths.

FIG. 3G shows the characteristics of the flexible MEG at different winding diameters.

FIG. 3H shows the real-time voltage changes of the MEG according to different bending speeds.

FIG. 3I shows the real-time changes in the current of the MEG according to different bending radii.

FIG. 4A illustrates a schematic of the KPFM measurement device for explaining the mechanism of MEG operation.

FIG. 4B shows the KPFM images of the two regions indicated in FIG. 4A.

FIG. 4C shows the histogram of the KPFM images for the two regions indicated in FIG. 4A.

FIG. 4D shows the zeta potential of PDDA/NaAlg mixtures at different ratios.

FIG. 4E shows the particle sizes of PDDA/NaAlg mixtures at different ratios.

FIG. 4F shows the KPFM image of a pure PEDOT ribbon.

FIG. 4G shows a histogram of the KPFM image of pure PEDOT ribbons.

FIG. 4H shows the log-log SAXS profiles of PDDA/NaAlg coacervate gel fibers at different ratios.

FIG. 4I shows the R value calculated from the representative 2D SAXS pattern illustrated in the inset of FIG. 4H.

FIG. 4J shows the XRD patterns of fibers with different PDDA/NaAlg ratios.

FIG. 4K shows the ionic conductivity of pure NaAlg and P5N20 coacervate gel.

FIG. 4L shows the MEG-related properties of fiber-type MEGs with different PDDA/NaAlg ratios.

FIG. 5A shows the surface electrostatic potential distribution of the NaAlg monomer.

FIG. 5B shows the surface electrostatic potential distribution of the PDDA monomer.

FIG. 5C shows the molecular structure of pure NaAlg.

FIG. 5D shows the molecular structures of pure PDDA and PDDA/NaAlg complex.

FIG. 5E shows the equilibrium structure of the PDDA/NaAlg system.

FIG. 5F shows the equilibrium structure of a pure NaAlg system.

FIG. 5G shows the simulated pore size distribution in the equilibrium structure illustrated in FIG. 5E and FIG. 5F.

FIG. 5H shows the visualization of free volume in the PDDA/NaAlg system.

FIG. 5I shows the visualization of free volume in a pure NaAlg system.

FIG. 5J shows the free volume fraction of the PDDA/NaAlg and pure NaAlg systems.

FIG. 5K shows the mean square displacement of the PDDA/NaAlg and pure NaAlg systems.

FIG. 6A illustrates a traditional MOS transistor model and code system for demonstrating a self-powered device.

FIG. 6B illustrates the operating principle of a fiber-type moisture electricity generator (MEG) based information transmission device.

FIG. 6C illustrates the transmission of Morse code information using the variation of the current signal generated by the fiber-type moisture electricity generator (MEG).

FIG. 6D is an example of integrating fibers into different forms of systems, representing knit fabric, a pentagonal shape, a spider web design, and a thread close with the word “NPL” inserted.

FIG. 6E illustrates a schematic of a biologically synaptic device induced by action potential and a MEG potential-driven artificial synapse device.

FIG. 6F shows the long-term potentiation (LTP) curves obtained at different pulse durations using a single moisture electricity generator (MEG) unit.

FIG. 6G shows the LTP curve obtained using a single MEG unit with a duration of 0.5 seconds.

FIG. 6H shows the long-term depression (LTD) curve obtained using a single moisture electricity generator (MEG) unit with a duration of 0.5 seconds.

FIG. 6I shows the LTP and LTD according to the number of VG pulses driven by a single MEG unit.

### DETAILED DESCRIPTIONS

Hereinafter, the embodiments of the present invention will be described in detail with reference to the attached figures. The present invention can undergo various modifications and can take on various forms; therefore, specific embodiments are illustrated in the figures and described in detail in the text. However, this is not intended to limit the present invention to the specific forms disclosed, and it should be understood that all modifications, equivalents, or alternatives that fall within the spirit and technical scope of the present invention are included. Similar reference numerals have been used for similar components while describing each figure. In the attached figures, the dimensions of the structures are shown enlarged for the sake of clarity of the present invention.

The terms used in this application are employed solely for the purpose of describing specific embodiments and are not intended to limit the present invention. Singular expressions shall be understood to include plural expressions unless the context clearly indicates otherwise. In this application, terms such as “comprising” or “having” are intended to specify the presence of features, numbers, steps, actions, components, or combinations thereof as described in the specification, and should not be understood as excluding the presence or addition of one or more other features, numbers, steps, actions, components, or combinations thereof. In the context of this specification, the term “about” may refer to approximately ±1%, ±2%, ±3%, ±4%, ±5%, ±6%, ±7%, ±8%, ±9%, or ±10% of the values stated in the specification.

In addition, the description of one aspect of the present invention may be similarly applied to the same or similar configurations or terms described in other aspects.

Unless otherwise defined, all terms used herein, including technical or scientific terms, shall have the same meaning as understood by a person of ordinary skill in the relevant field of technology to which the present invention pertains. Terms that are defined in commonly used dictionaries should be interpreted to have meanings consistent with their context in the relevant technology, and unless explicitly defined in this application, they shall not be interpreted in an idealized or overly formal manner.

The moisture electricity generator according to an embodiment of the present invention may comprise a core including a conductive polymer; and a shell that at least partially surrounds the core and includes a complex coacervate containing ions.

In the context of this specification, the term “moisture electricity generation” refers to the process of generating electrical energy by utilizing the moisture in the environment. This has the potential to harvest power using natural elements such as humidity. Moisture electricity generation technology is environmentally friendly and has the potential to provide self-powered solutions in various application fields. Such generation systems can be effectively utilized in small devices like wearable devices or sensors, supporting sustainable energy supply.

In the context of this specification, the term “core” may refer to a specific central structure and can include a conductive polymer. This core plays a crucial role in generating power through electrical conductivity. A core that includes a conductive polymer can provide high conductivity and mechanical flexibility, allowing it to function effectively in various environments.

As long as the aforementioned functions are performed, the material of the conductive polymer included in the core is not specifically limited. In one embodiment, the conductive polymer may include PEDOT (poly(3,4-ethylenedioxythiophene)). PEDOT (poly(3,4-ethylenedioxythiophene)) is a conductive polymer with excellent electrical conductivity and high mechanical flexibility, widely used in various applications. This polymer exhibits outstanding conductivity and plays a crucial role in electronic devices such as photovoltaic cells and sensors. PEDOT provides excellent environmental stability and has the potential to be integrated into various forms of devices due to its lightweight and flexible characteristics. The material of the conductive polymer included in the core is not specifically limited, and other conductive polymers may include polyaniline (PANI), polythiophene (PTh), polypyrrole (PPy), poly(3-hexylthiophene) (P3HT), doped PEDOT (C-PEDOT), doped poly(3,4-ethylenedioxythiophene) (PDOT), polythiophenes (PTAA), poly(3,4-ethylenedioxythiophene) (PTB7), graphene composites (PANI/graphene), and polyvinyl alcohol (PVA/Ag) containing silver nanoparticles, among others. Thus, various conductive polymers exist, and each can be effectively utilized in specific application fields according to their characteristics.

In the context of this specification, the term “shell” refers to an external structure that surrounds the core. This shell is composed of a complex coacervate and serves to complement and protect the functions of the core. The shell can form a potential through interaction with moisture and can increase the mobility of ions. Such a structure may enhance the stability of the overall device and enable effective energy harvesting.

A potential gradient may arise from the moisture or wettability difference between the core and the shell. This potential gradient can facilitate the movement of ions, thereby helping to enhance the efficiency of power generation. The potential generated due to the moisture difference induces electron movement between the electrodes, which has the potential to maximize power output. This process enhances the functionality of the moisture electricity generator (MEG) and can provide a foundation for stable operation in various environments. Additionally, this potential gradient can support the effective harvesting of electrical energy by regulating the ion distribution within the complex coacervate.

In the context of this specification, the term “complex coacervate” refers to a structure formed by the combination of different polymers. It contains ions and can assist in facilitating charge transport. The complex coacervate is formed through the interaction of two or more substances, and this interaction plays an important role in enhancing the performance of the moisture electricity generator (MEG). This structure has the potential to promote ion diffusion and contribute to solving various issues that may arise during the power generation process.

As long as the aforementioned functions are performed, the materials of the complex coacervate are not specifically limited. In one embodiment, the complex coacervate may include polydiallyldimethylammonium chloride (PDDA) and sodium alginate (NaAlg). PDDA is a polymer that carries a positive charge and can assist in facilitating ion exchange and charge transport. This means that PDDA can contribute to enhancing the power generation efficiency of the moisture electricity generator by facilitating the diffusion of ions. On the other hand, sodium alginate (NaAlg) carries a negative charge and exhibits excellent biocompatibility and adhesive properties, allowing it to function reliably in various environments. NaAlg can absorb moisture well and can exist in a gel form, providing electrical conductivity and serving to retain and transport ions. The combination of these two substances can optimize charge separation and ion mobility within the complex coacervate, thereby contributing to maximizing the performance of moisture-based electricity generation.

By selecting materials as described above, the process and principle by which the device according to the embodiment of the present invention generates electricity from moisture are as follows: First, the complex coacervate formed from the combination of PDDA and NaAlg has the property of absorbing moisture and releasing ions upon contact with humidity. PDDA carries a positive charge and interacts with negatively charged NaAlg, leading to charge separation and facilitating the diffusion of ions. This charge separation forms a potential between the core and the shell, resulting in a potential gradient that accelerates the movement of ions. In this process, the conductive polymer PEDOT, which is included in the core, provides high conductivity, playing a role in converting the formed potential into electrical energy. As the complex coacervate of PDDA and NaAlg stably maintains the charge while the moisture absorbed from the humidity moves in ionic form, the voltage difference between the core and the shell increases, ultimately generating electrical energy. This process continuously occurs through interaction with moisture, enabling efficient power generation.

However, the complex coacervate used in the present invention is not limited to the above materials. Non-limiting examples of complex coacervate materials that perform similar functions include: polyacrylic acid (PAA), polyvinyl alcohol (PVA), carboxymethyl cellulose (CMC), polycarbonate (PC), polyurethane (PU), polymethacrylic acid (PMA), poly(L-lactic acid) (PLA), poly(isobutylene) (PIB), polyamide (PA), hydroxypropyl methylcellulose (HPMC), sodium caseinate, poly(dimethylsiloxane) (PDMS), conductive polymer blends, silica-based hydrogels, conductive epoxy resins, sodium alginate (NaAlg) mixtures, methylcellulose (MC), polypyrrole (PPy), polythiophene (PTh), polymer/graphene composites, poly(vinylidene fluoride) (PVDF), poly(3-hexylthiophene) (P3HT), carboxymethyl starch (CMS), peptide-based gels, functional polyurethanes, acrylic polymers, hydrogel-based composites, conductive nanoparticle composites, conductive ceramics, polyvinylidene fluoride (PVDF), hydrogelated polyurethane, composites including metal nanoparticles, and conductive carbon black. These materials may possess similar charge transport and ion retention and transport properties, which can contribute to the enhancement of the performance of the moisture electricity generator (MEG).

The device according to an embodiment of the present invention performs the aforementioned functions and does not exclude the addition of additional components for obtaining electrical energy. In one embodiment, the moisture electricity generator may further include a peripheral electrode formed on the shell. The role of the peripheral electrode is to complete the circuit for obtaining electrical energy. This connects the potential generated in the core to the external circuit, allowing for effective collection and transmission of the generated power. The peripheral electrode induces the flow of current through the potential gradient and provides a foundation for the moisture electricity generator to operate stably. As a result, the overall performance of the device can be improved.

As long as the aforementioned function is performed, the peripheral electrode can be formed from any conductive material. In one embodiment, the peripheral electrode may include a metal. In one embodiment, the peripheral electrode may include copper. Non-limiting examples of possible materials for the peripheral electrode include: copper, aluminum, gold, silver, nickel, tin, iron, chromium, zinc, titanium, manganese, cobalt, lead, palladium, selenium, tantalum, vanadium, indium, stellite, carbon, graphene, graphite, conductive polymers, silver nanoparticles, metal nanowires, sputtered metal thin films, magnesium, molybdenum, tungsten, indium tin oxide (ITO), platinum, osmium, radium, ruthenium, halogenated metals, nanoscale metal particles, conductive ceramics, metal composites, oxide semiconductors, silver nanowires, copper nanowires, aluminum nanowires, metal-organic composites, alloy metals, plated metals, and plastic conductive coatings, among others.

The device according to an embodiment of the present invention is not necessarily limited in its shape as long as its functionality is maintained. However, the implementer may process the device of the present invention into an appropriate shape according to its intended use, and the properties of the materials may also be taken into consideration. In one embodiment, the core and the shell may be formed in a fiber form.

When the moisture electricity generator (MEG) is formed in a fiber form, there are several advantages. First, the fiber form provides flexibility and lightweight characteristics, making it easy to use in various environments. This is particularly useful in applications such as wearable devices, as it does not interfere with the wearer's activities. Second, the fiber structure can form a large surface area, which increases the contact area with moisture. As a result, the moisture absorption efficiency is enhanced, and the power generation performance can be improved. Third, fibers can be woven or knitted into various shapes, providing design freedom and increasing the potential to integrate various functions.

In this way, when produced in a fiber form, the peripheral electrode can be appropriately formed. In one embodiment, the moisture electricity generator may further include a peripheral electrode formed on the shell. In one embodiment, the peripheral electrode may be formed of a metal wire that spirally wound around the fiber-shaped core and shell. There are several advantages to forming the peripheral electrode with a metal wire as described above. First, the metal wire provides excellent conductivity, facilitating the flow of power and allowing for efficient collection of electrical energy and its transfer to an external circuit. Second, the spiral wrapping shape can maximize the contact area of the electrode, contributing to the enhancement of the potential gradient. This can help increase the voltage generated during the electricity generation process. Third, the metal wire is flexible, allowing for deformation along with the fiber-shaped core and shell, thus maintaining comfort and stability during wear. In one embodiment, the moisture electricity generator can generate electrical energy from the potential gradient between the core and the peripheral electrode.

Meanwhile, the method for manufacturing a moisture electricity generator (MEG) according to an embodiment of the present invention may include forming a shell that at least partially surrounds the outer surface of a core comprising a conductive polymer, the shell comprising a complex coacervate containing ions. The role of forming the shell is to maximize the functionality of the moisture electricity generator through the interaction between the core and the shell. In this process, the shell surrounds the core made of a conductive polymer, creating a structure that can protect and complement the electrical conductivity of the core. The shell composed of the complex coacervate absorbs ions through interaction with moisture, thereby contributing to the generation of an electric potential gradient and the production of electrical energy.

In one embodiment, the conductive polymer may be prepared to include PEDOT (poly(3,4-ethylenedioxythiophene)). In one embodiment, the complex coacervate may be prepared to include polydiallyldimethylammonium chloride (PDDA) and sodium alginate (NaAlg). In one embodiment, it may further include a peripheral electrode forming step for forming a peripheral electrode on the shell. In one embodiment, the peripheral electrode may be prepared to include a metal.

In one embodiment, the core is prepared in a fiber form, and the shell can be formed in a fiber form that wraps around the core. In the manufacturing method according to the present invention, one example of a method for producing the core and shell structure in fiber form may include the following wet spinning process. This process is a method of forming fibers by sequentially using a conductive polymer solution and a complex coacervate. First, a conductive polymer (PEDOT) solution is prepared and introduced into the spinning process through a syringe connected to a micro-injection pump. At this time, the spinning speed and the concentration of the solution are adjusted to obtain an appropriate fiber thickness and mechanical strength. Subsequently, the spun fiber solidifies as it enters a coagulation bath. The components of the coagulation bath generally include an organic solvent and an electrolyte, which help the spun fiber to coagulate into a stable form. Next, the formed fiber enters a washing process to remove residual solvent, and if necessary, surface properties can be improved through post-treatment. Thereafter, the process may include immersing the fiber in a mixed solution of NaAlg and PDDA to form a complex coacervate. In this process, the two polymers are formed as a complex coacervate on the fiber surface, and then dried again to ultimately complete a moisture electricity generator in fiber form with a core and shell structure. However, the scope of the present invention is not limited to the wet spinning process as described above.

In one embodiment, a peripheral electrode forming step for forming a peripheral electrode on the shell may further be included. In one embodiment, the peripheral electrode may be prepared to include a metal. In one embodiment, the peripheral electrode may be prepared to include copper. In one embodiment, the core may be prepared in a fiber form, and the shell may be formed in a fiber form that wraps around the core. In one embodiment, a peripheral electrode forming step for forming a peripheral electrode on the shell may further be included. In one embodiment, the peripheral electrode may be formed by spirally winding a metal wire around the fiber form of the core and shell.

On the other hand, the electricity generator according to the embodiment of the present invention may be an electricity generator that connects the moisture electricity generator (MEG) according to the embodiment of the present invention to a self-powered sensor or an artificial synapse device.

In the context of this specification, the term “self-powered sensor” refers to a sensor that generates energy on its own to operate without an external power supply. Such sensors typically respond to changes in the environment to collect information and transmit signals based on that information. Self-powered sensors can be particularly useful in situations where continuous battery replacement is challenging, contributing to increased energy efficiency and minimized maintenance. Therefore, they enable reliable data collection in various environments.

In the context of this specification, the literal meaning of “artificial synapse device” refers to a device that processes and transmits information by mimicking biological synapses. Such devices have the potential to generate responses to input signals through actions similar to neural networks, and can implement learning and memory functions. The artificial synapse device plays an important role in the fields of artificial intelligence and robotics, and can further contribute to the integration with neuroscience research.

Non-limiting examples of applications where the self-powered sensor or artificial synapse device as described above can be used include environmental monitoring systems, smart home automation, healthcare monitoring devices, wearable technology, robotic control systems, human-machine interfaces, brain-machine interfaces, and sensor systems for autonomous vehicles. These applications may promote sustainable energy use and help improve the overall efficiency of the systems.

The following describes embodiments of the present invention. However, the embodiments described below are merely some forms of the present invention, and the scope of the present invention is not limited to the embodiments provided herein.

### Design and Preparation of Fiber-Based MEG

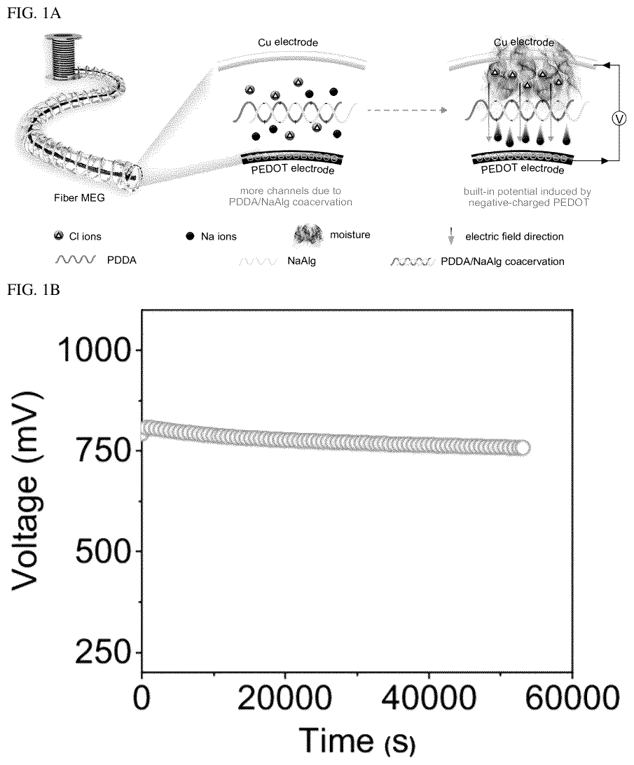

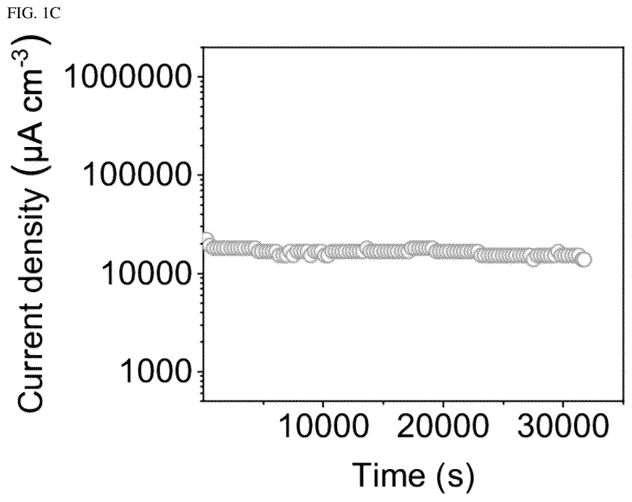

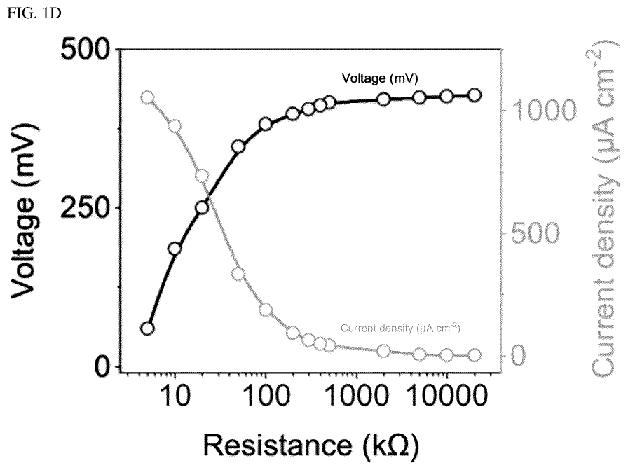

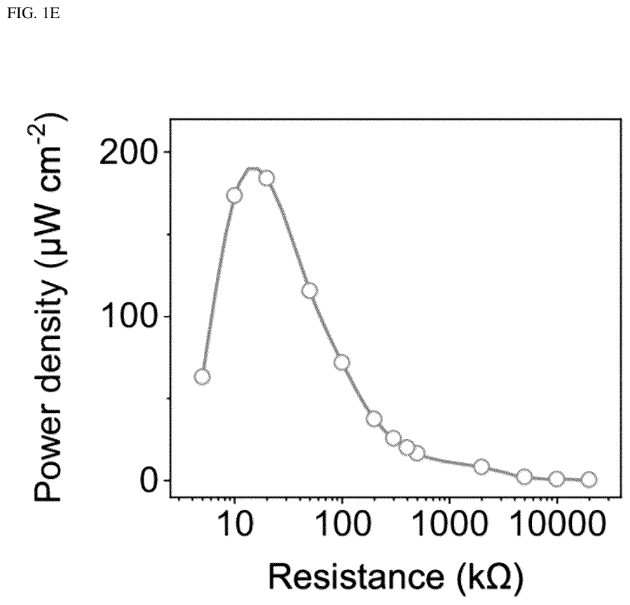

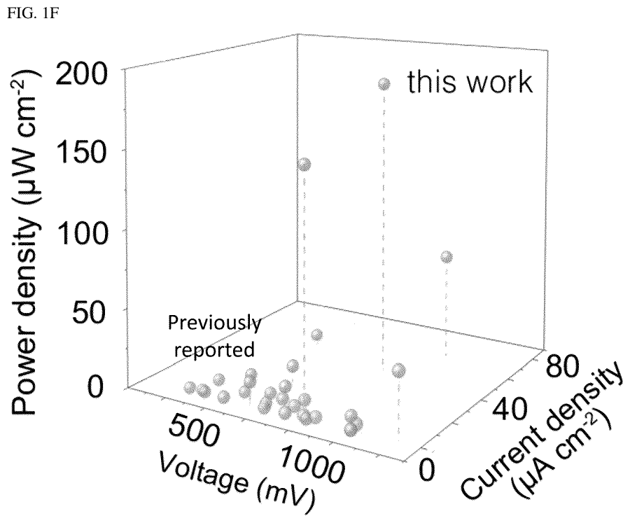

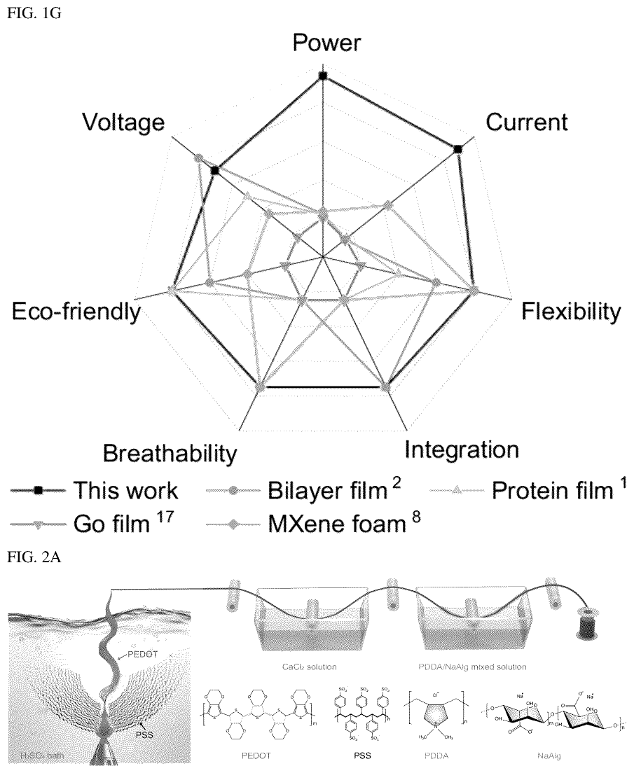

A high-performance moisture electricity generator (MEG) was fabricated, comprising a PEDOT core and a PDDA/NaAlg coacervate gel shell (PEDOT@PDDA/NaAlg), surrounded by a copper wire electrode (FIG. 1A). In this device, the polymer coacervate gel made of PDDA and NaAlg, which have opposite charges, was utilized as the energy generation part of the MEG. Therefore, the PDDA/NaAlg coacervate can be considered a homogeneous electric generation material, distinct from the bilayer heterostructure created using two individual polymer electrolytes. The originally negatively charged PEDOT nanoribbons serve as the internal electrode, while the flexible and thin copper wire acts as the external electrode. The PEDOT electrode induces a built-in potential when assembled with the copper metal electrode, generating a driving force that promotes the directional diffusion of charge carriers, thereby enhancing the performance of the MEG. Additionally, when PDDA and NaAlg coalesce, the strong polymer-polymer combination increases the free volume of the gel, resulting in the release of a large number of mobile ions. The increased number of free mobile ions and the increased free volume after coacervation effectively enhance the output performance of the MEG by increasing the number of charge carriers and accelerating ion diffusion (FIG. 1A). Interestingly, the fiber-based MEG exhibited an outstanding open-circuit voltage of 0.8 V and a short-circuit current density of 1.05 mA/cm² under ambient conditions (relative humidity of 20% and 25° C.) (FIG. 1B and FIG. 1C). Furthermore, this device operated stably for approximately 15 hours, outputting a high power density of about 178 W/cm² (FIG. 1D and FIG. 1E). This high performance makes it stand out among various MEGs reported under similar conditions (FIG. 1F).

In addition to the excellent energy generation performance mentioned above, the moisture electricity generator (MEG) contributes to environmentally friendly and sustainable production, demonstrating outstanding biocompatibility, flexibility, weavability, integrability, and breathability, thereby proving comprehensive advantages over existing MEGs. Notably, it is rare to demonstrate an integrated MEG device that possesses high mechanical flexibility simultaneously. This is primarily due to the use of highly conductive hard metals as electrodes, which necessitate sealing one side in most thin-film MEGs, significantly limiting flexibility and breathability. By using flexible electrodes to fabricate a fiber-structured device, these issues can be effectively addressed. The core-shell structure of the fiber forms a self-sealing configuration that exposes only the outer surface to moisture and generates an ion concentration gradient. The microelectrodes within the fiber greatly enhance the overall flexibility of the device. Although several fiber-type MEGs have been reported, they still face challenges such as intermittent power generation, performance deficiencies, and limited flexibility. To address these issues, the inventor's approach involves using ultra-flexible conductive polymer fibers surrounded by a self-sealing complex coacervate as electrodes. This design not only ensures mechanical flexibility with a soft PEDOT core electrode but also significantly enhances output performance due to the synergistic effects of complex coacervation and built-in potential. Furthermore, weaving these fibers into a fabric improves breathability, which is an important feature for practical applications. Moreover, since all components are environmentally friendly, the inventor's core-shell fibers ensure biocompatibility. As shown in the radar chart of FIG. 1G, the inventor compared their MEG with several representative MEGs. The values of voltage, current density, and power density are graphically represented, and the characteristics of flexibility, eco-friendliness, integrability, and breathability are also ranked, showcasing the unique and comprehensive properties of the inventor's MEG device.

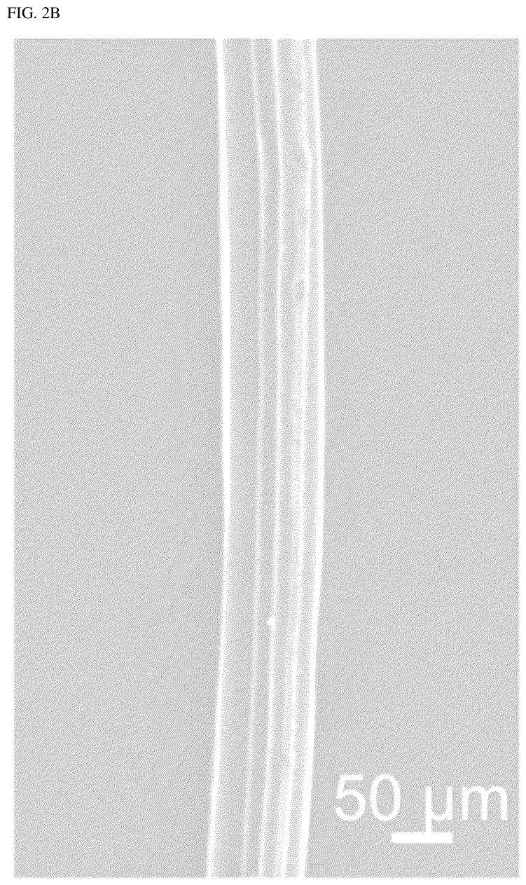

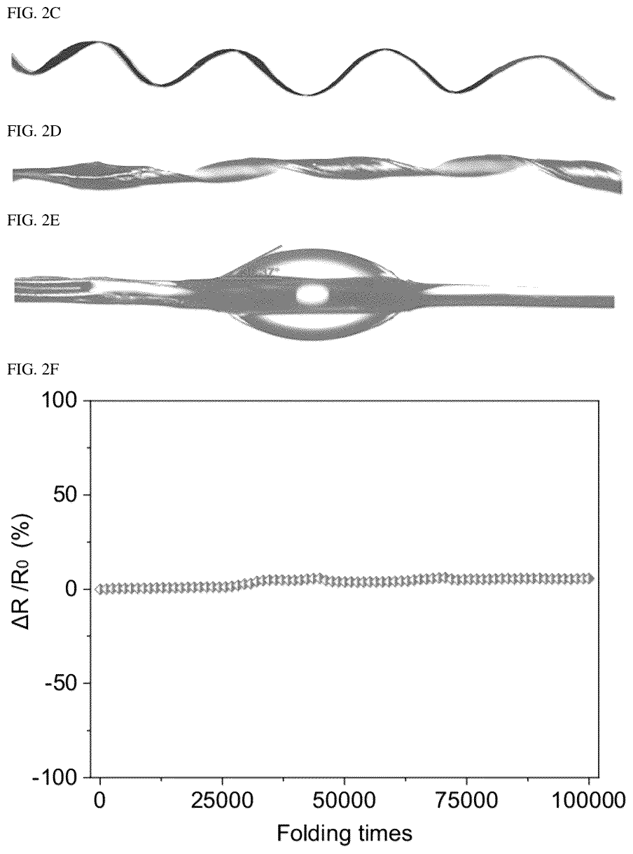

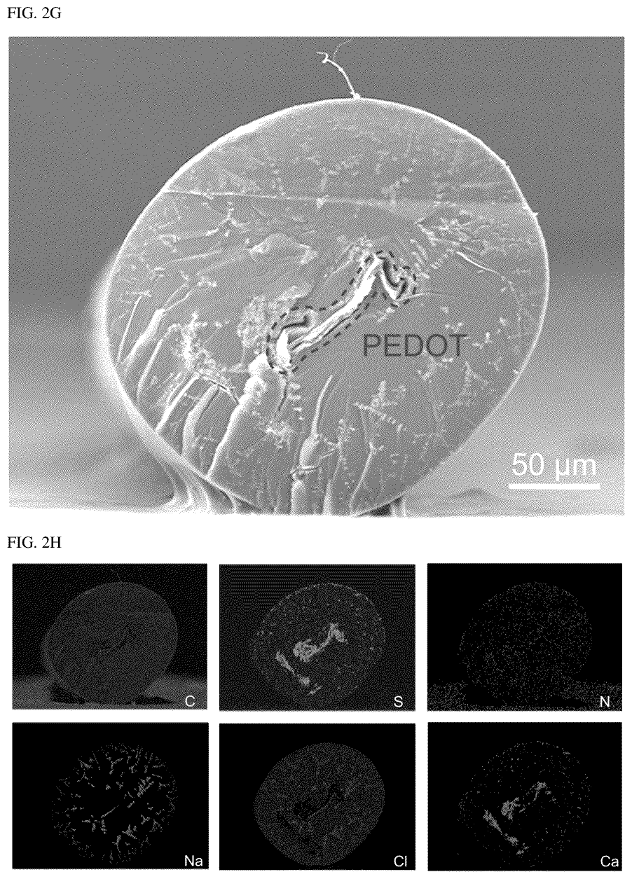

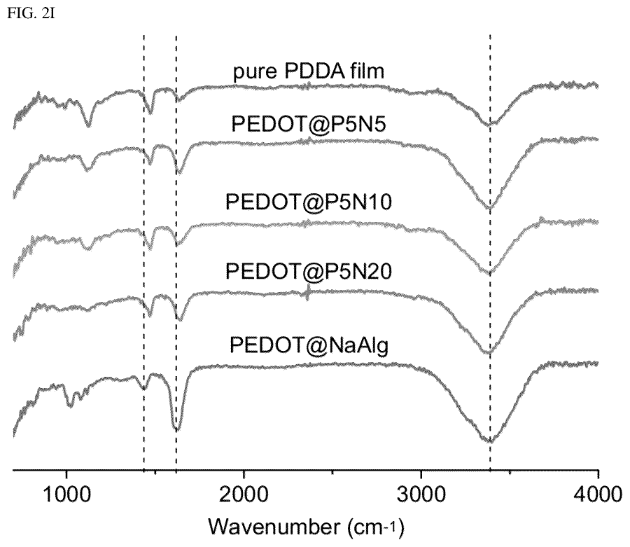

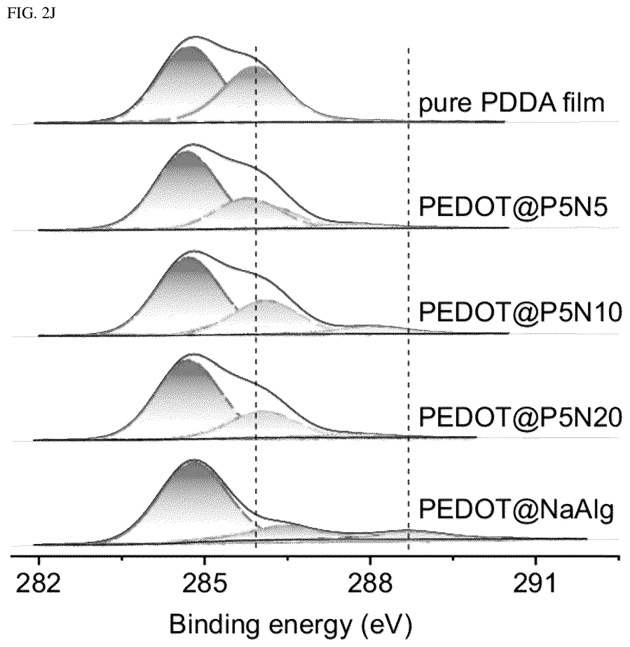

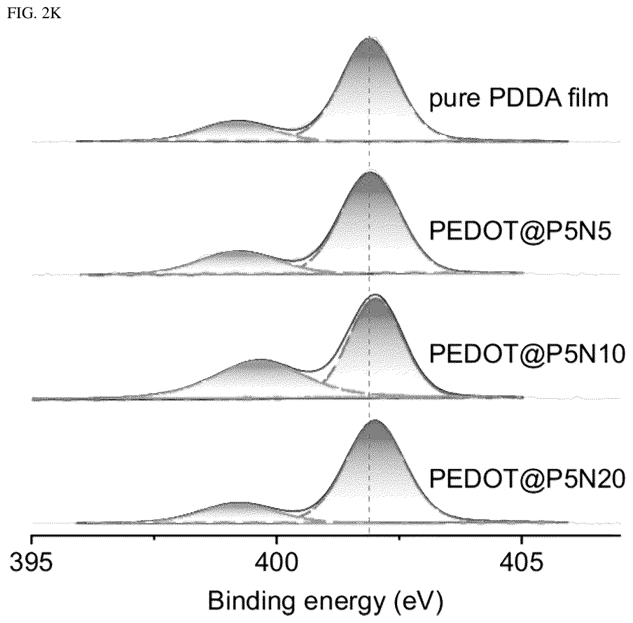

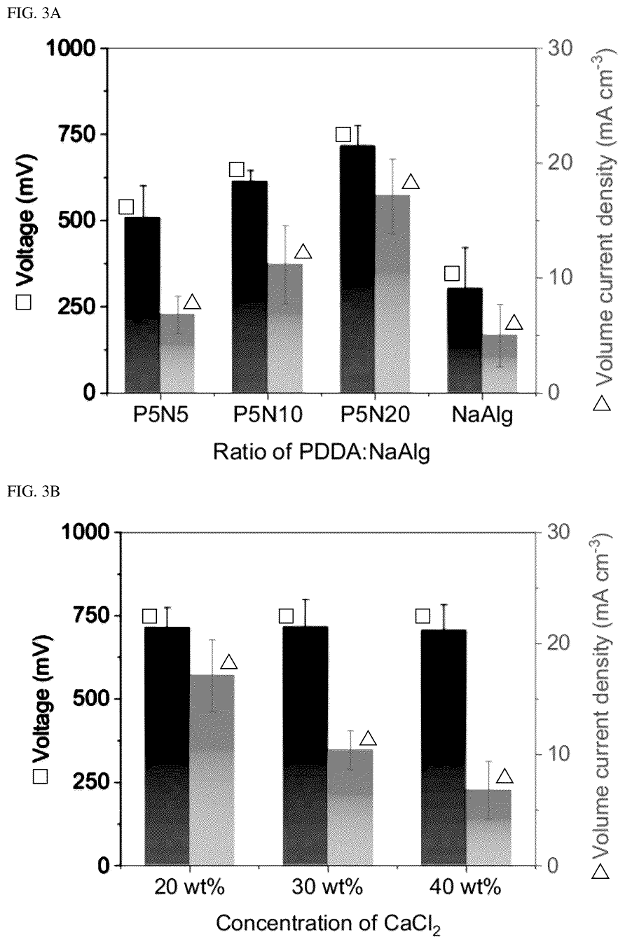

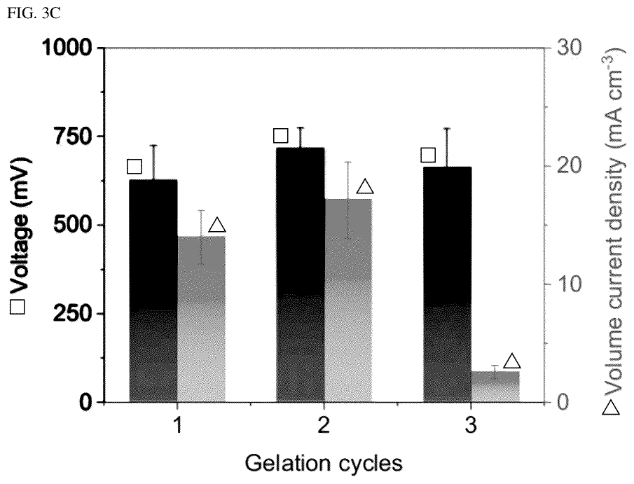

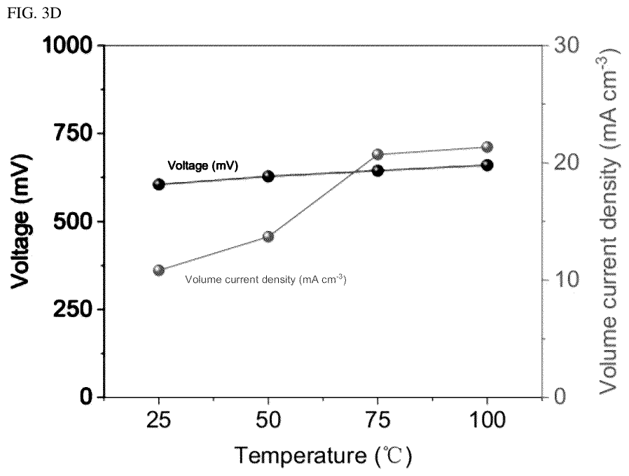

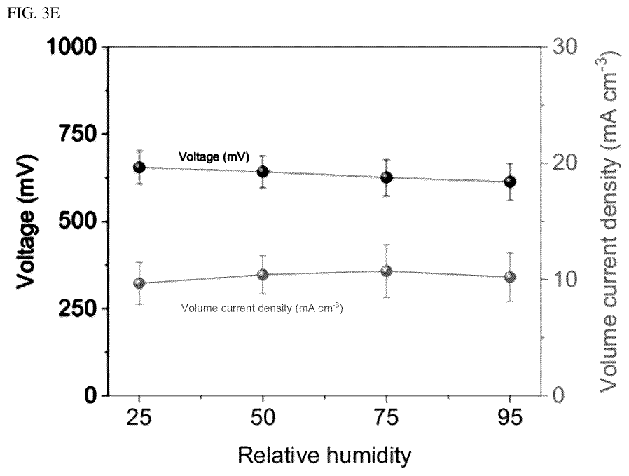

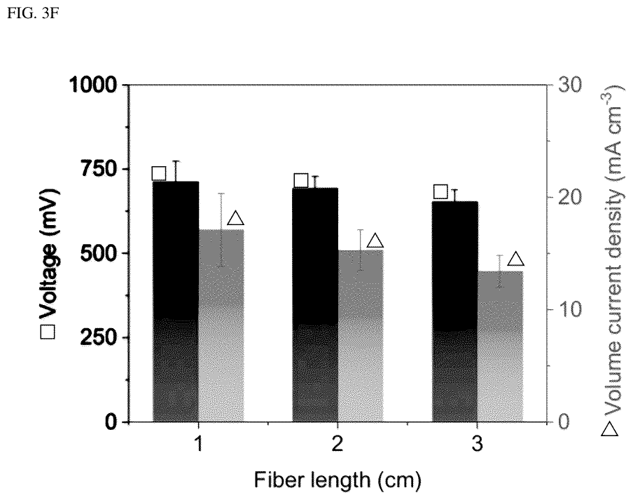

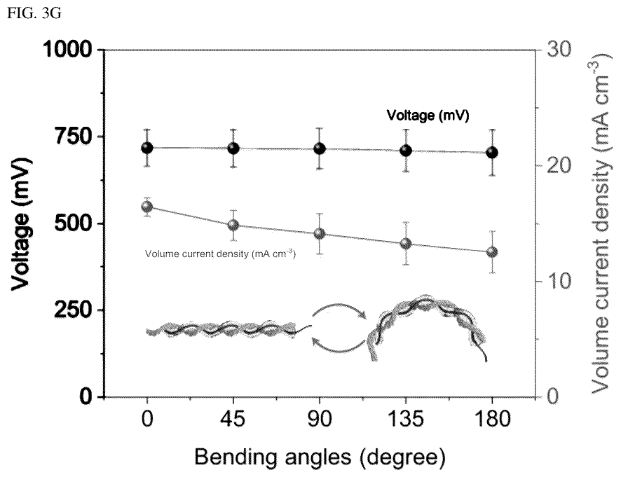

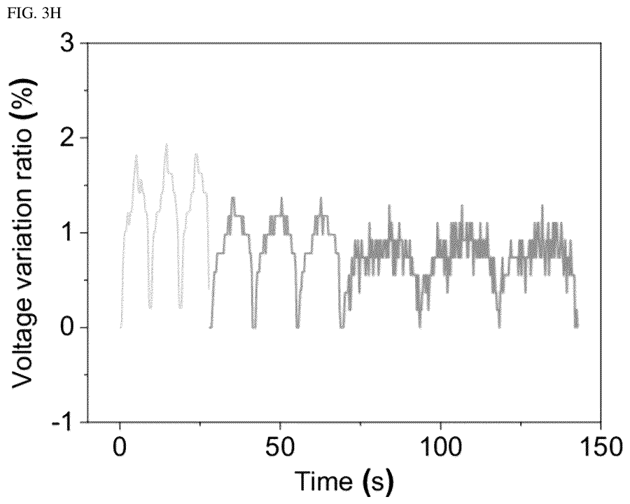

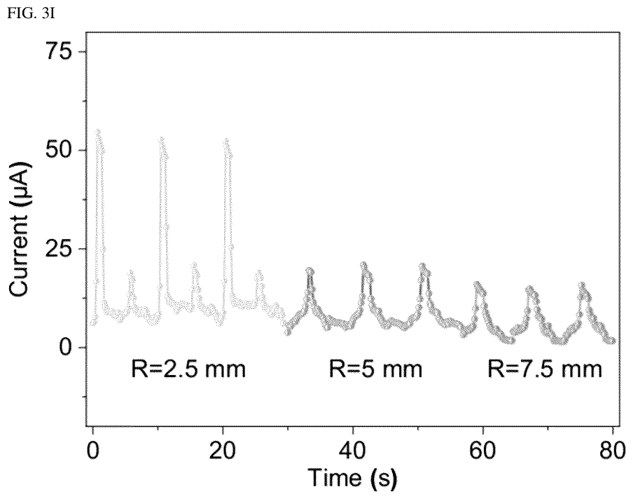

An optimal device fabrication pathway based on a two-step wet spinning process has been realized through extensive experimental exploration and condition optimization. First, negatively charged highly conductive PEDOT ribbons were prepared via large-scale continuous wet spinning (FIG. 2A). Notably, the concentration of the PEDOT solution and the spinning speed significantly affected the conductivity and mechanical strength of the PEDOT ribbons. The PEDOT samples obtained using the optimized spinning solution (concentration 3.9%, spinning speed 2 mL/h) exhibited an electrical conductivity of approximately 4000 S/cm, which is one of the highest conductivity values reported for fiber-type PEDOT materials. Structural characterization results indicated that the PEDOT samples had a unique ribbon shape with a width of about 100 m and a thickness of 2 m (FIG. 2B). In particular, the PEDOT ribbons are presumed to have topological grooves on their surface that help disperse mechanical stress during deformation (FIG. 2B). The excellent flexibility of the PEDOT ribbons was demonstrated through various mechanical tests. The PEDOT ribbon core withstood bending, folding, twisting, and torsion at various angles without structural failure (FIG. 2C and FIG. 2D). Furthermore, even after being folded over 100,000 times, the PEDOT ribbons showed no structural damage or decrease in conductivity, making them ideal electrodes for flexible integrated MEGs with high electrical conductivity and outstanding flexibility (FIG. 2F). Moreover, the PEDOT ribbons possess hydrophilicity (water contact angle of 36°), resulting in excellent surface interactions with the complex coacervate PDDA/NaAlg gel (FIG. 2E).

Next, the PEDOT@PDDA/NaAlg fibers were continuously produced by sequentially immersing PEDOT ribbons in a 20% CaCl₂) solution and an optimized mixture of PDDA/NaAlg at a ratio of 5:20. Cross-sectional analysis of the resulting complex coacervate gel fibers revealed a cylindrical structure with an average diameter of 200 μm (FIG. 2G). Energy-dispersive X-ray spectroscopy (EDS) mapping indicated a predominant distribution of sulfur (S) derived from PEDOT in the core, while a uniform distribution of nitrogen (N) derived from PDDA was observed in the fiber shell. Additionally, the mapping results showed that sodium ions (Na) were more concentrated in the outer region of the shell. This Na concentration gradient was spontaneously formed during the synthesis process and may help accelerate ion diffusion and enhance the performance of the moisture electricity generator (MEG) (FIG. 2H). These results confirm that the PEDOT ribbon core and the complex coacervate gel shell were prepared through a two-step continuous and rapid mass production process.

To investigate the interaction between PDDA and NaAlg, various characterization experiments were conducted. Fourier-transform infrared spectroscopy (FT-IR) analysis showed that the absorbance at 1600 cm⁻¹, resulting from the carbonyl stretching of NaAlg after the addition of PDDA, exhibited a blue shift in all PEDOT@PDDA/NaAlg fibers, indicating an electrostatic interaction between the carboxyl groups of NaAlg and the quaternary ammonium groups of PDDA (FIG. 2I). Additionally, in the high-resolution C1s X-ray photoelectron spectroscopy (XPS) profile, the C=O and C—N peaks of the complex coacervate showed a red shift, while the quaternary ammonium nitrogen peak in the high-resolution N1s spectrum exhibited a blue shift compared to pure NaAlg and pure PDDA (FIG. 2J and FIG. 2K). This primarily suggests that complex coacervation occurred between the carboxyl groups of NaAlg and the quaternary ammonium groups of PDDA. At the same time, the electrostatic interactions between these groups altered the chemical environment of Ca and Cl, resulting in significant shifts in the 2p peaks of Ca and Cl. These results confirm the complex coacervation of PDDA and NaAlg within the fibers.

### Conditional Experiments for Optimizing MEG Performance

The effects of the complex coacervate gel structure and testing conditions on the performance of the moisture electricity generator (MEG) were comprehensively investigated. Starting with the influence of the PDDA/NaAlg ratio, it was confirmed in the gelation experiments that the mixture hardly precipitated when the volume ratio of NaAlg to PDDA was less than 4. The PDDA/NaAlg complex coacervate gel was prepared by including Ca ions in the mixed solution. The MEG using pure NaAlg generated a voltage of 300 mV and a current density of 5 mA/cm³. Similarly, pure PDDA produced a voltage of 200 mV and a much smaller current density. However, when the complex coacervate gel was formed, both the output voltage and current significantly increased. As the NaAlg content increased, the average output voltage rose from 500 mV to 750 mV, and the volumetric current density increased from 7 mA/cm³ to 17 mA/cm³ at 20% relative humidity and 25 degrees. Additionally, the complex coacervate gel was diversified by adjusting the charging ratio of NaAlg and PDDA, with optimal MEG performance achieved at a ratio of 5:20. Subsequently, the effect of CaCl₂) concentration on gelation was evaluated, showing optimal performance at 20 weight %. The low gelation rate realized at lower CaCl₂) concentrations may favor MEG performance due to the uniform pores induced during the gelation process. Furthermore, the impact of the number of gelation cycles on the manufacturing of complex coacervate gel fibers was investigated. The MEG exhibited optimal performance after two gelation cycles, which may provide an appropriate thickness for electricity generation. Testing the properties of fibers of various lengths resulted in similar voltages being generated, while the current increased proportionally with length, laying the foundation for the large-scale application potential of fiber-type MEGs.

Additionally, the effects of test conditions including temperature and relative humidity (RH) on the performance of the moisture electricity generator (MEG) were investigated. The device operated reliably as the temperature increased from 25° C. to 100° C., and its performance showed slight improvement. The operating temperature range is very broad compared to reported values. Furthermore, the output voltage and current exhibited only a slight increase with rising RH. This may be attributed to the excellent hydrophilicity and moisture retention properties of the fibers. Even at low RH levels, the complex coacervate gel fibers absorbed sufficient moisture for ionic dissociation and diffusion. As a result, further increases in RH did not significantly enhance MEG performance. Overall, the broad operating temperature range of the MEG, stable operation within the RH window, and high power density at low RH provide the capability to operate in most regions of the Earth.

The flexibility of the materials and device is essential for the development of advanced flexible wearable technology. Subsequently, the characteristics of the moisture electricity generator (MEG) were investigated under various deformation modes. Initially, the bending and folding capabilities of the fiber-type MEG were manually characterized at various angles and repetitions. As the bending angle changed, the voltage was maintained relatively stably, while the current slightly decreased in a steady state. This may be due to changes in resistance between the external electrodes and the complex coacervate gel, as well as changes in the contact area during deformation. In addition to the aforementioned passive static tests, dynamic bending studies were conducted on the fiber-type MEG to monitor real-time changes in electrical signals. The analysis of output voltage variation revealed noticeable peaks during bending, and the MEG returned to its initial value when returning to a flat state. The voltage fluctuation of the MEG due to changes in bending frequency was only about 2%. Furthermore, as the bending frequency increased, the rate of change in current significantly increased. These results emphasize that the fiber-type MEG possesses excellent resolution and recognition capabilities in demonstrating dynamic bending, suggesting its potential in the field of self-powered human-machine interaction.

### Operating Mechanism of Fiber-Type MEG

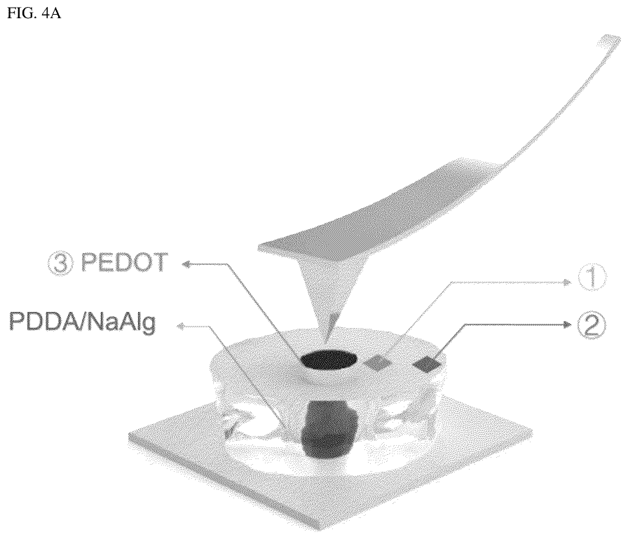

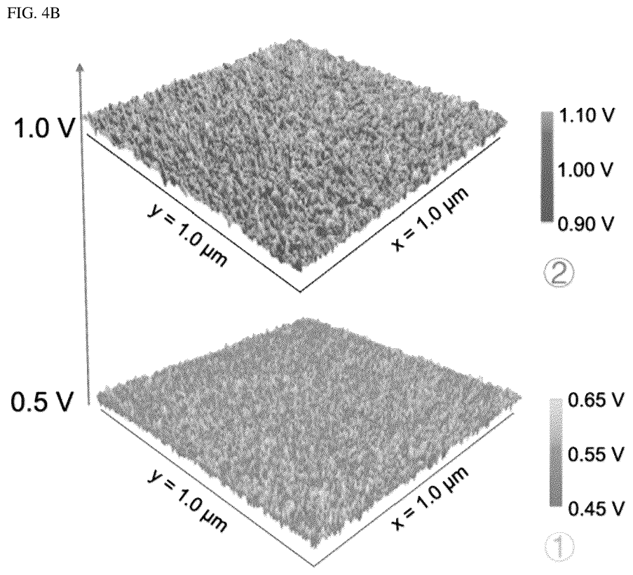

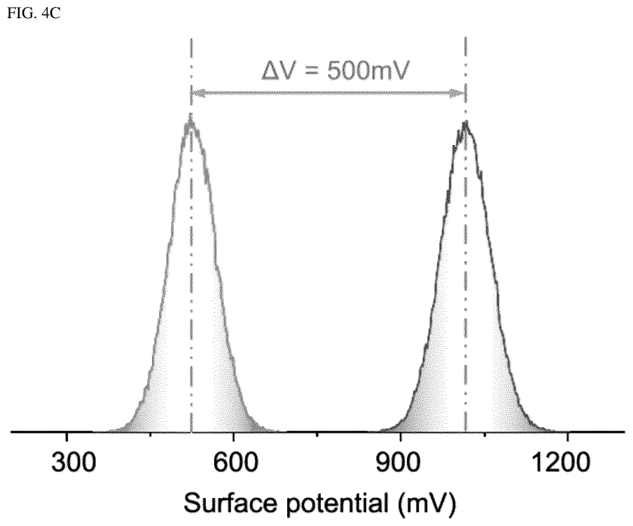

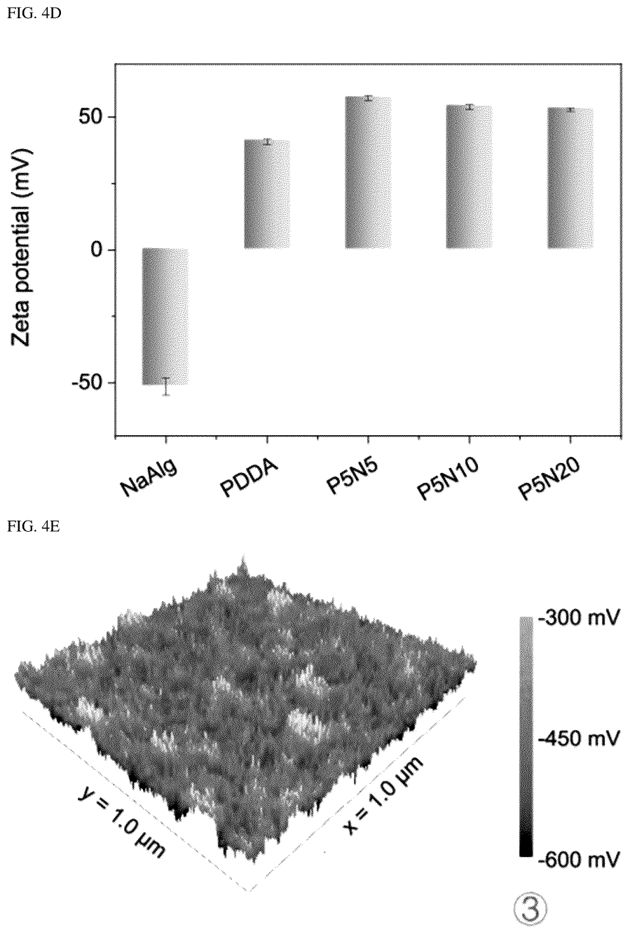

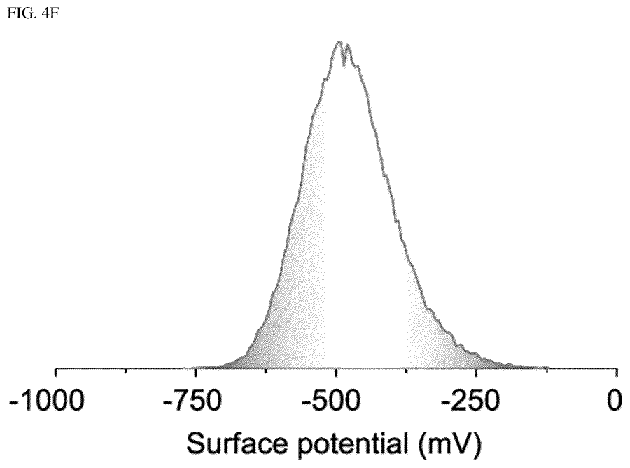

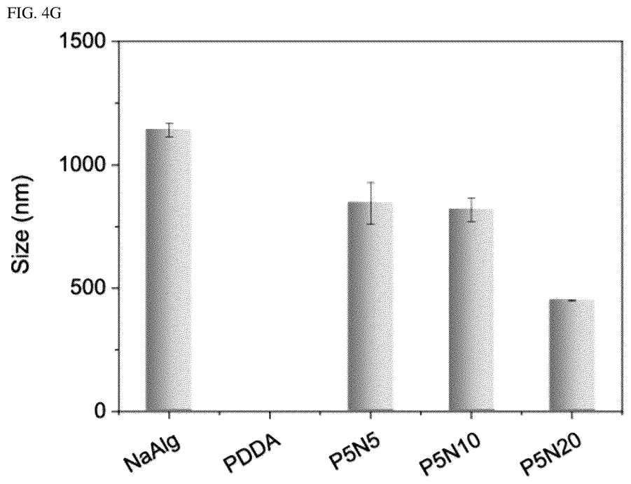

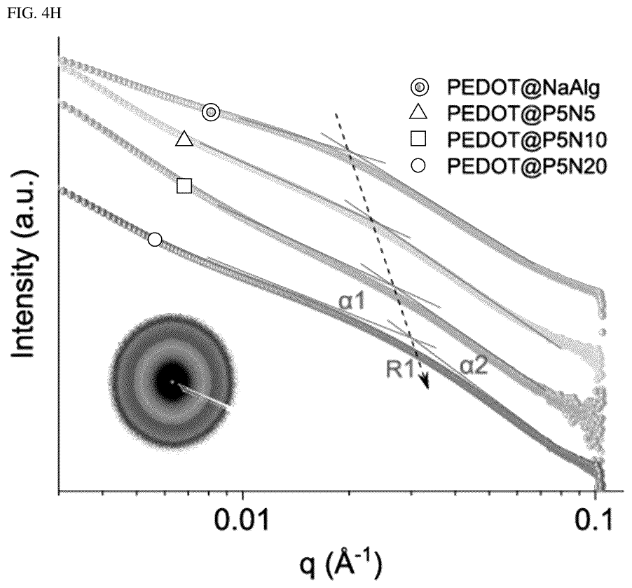

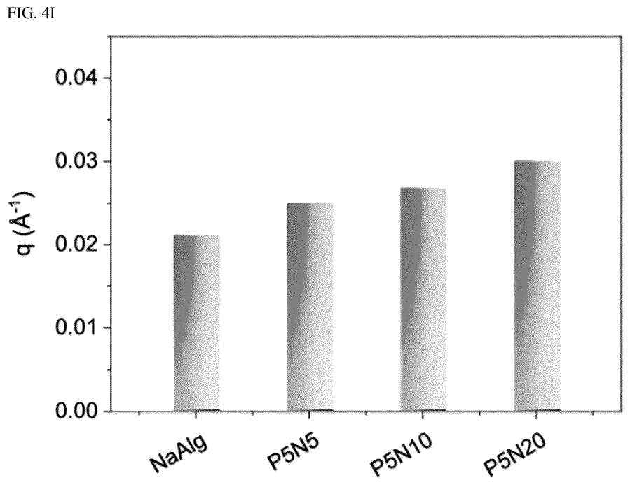

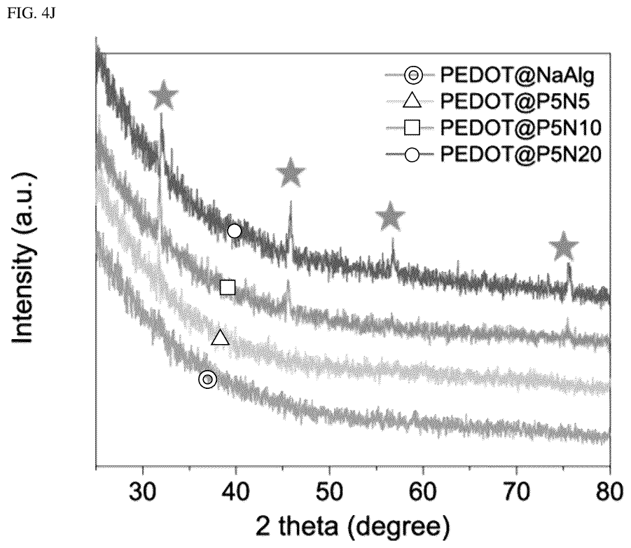

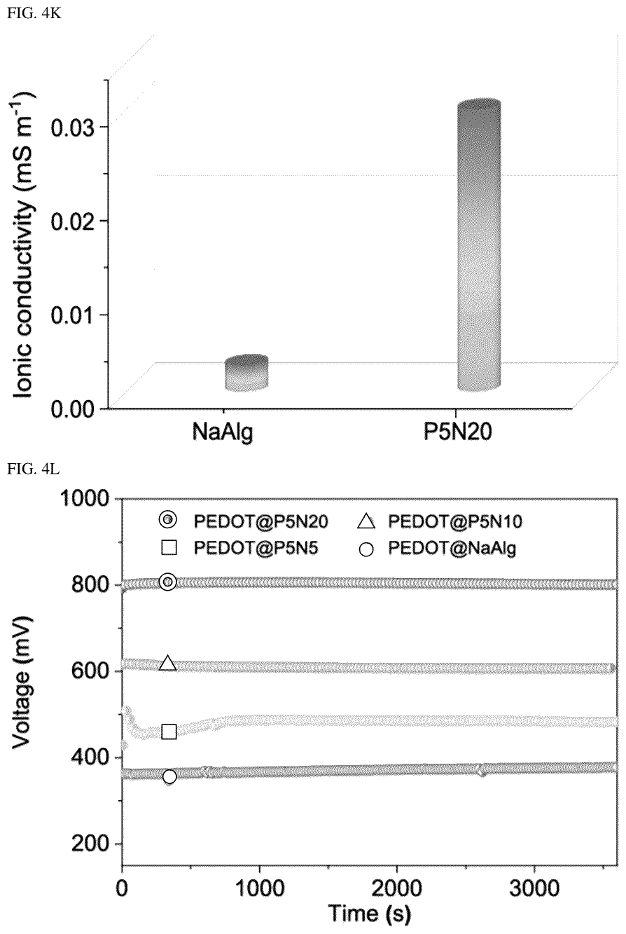

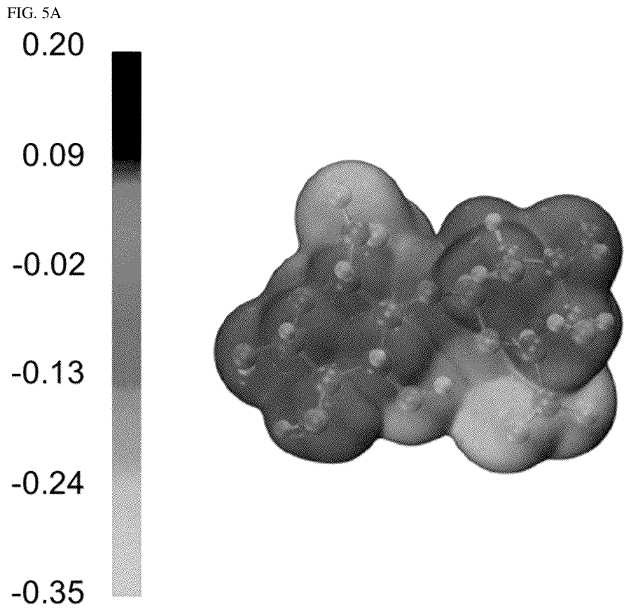

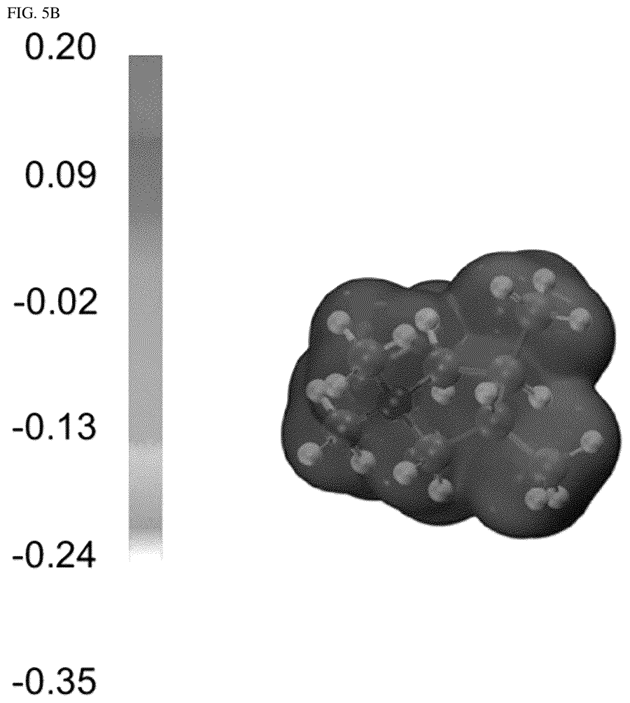

The mechanism behind the excellent performance of the moisture electricity generator (MEG) has been explored through in-depth experiments and simulations. Using a Kelvin probe force microscope (KPFM), a significant surface potential difference (up to 500 mV) was observed between specific regions within the core and shell areas of the coacervate gel fibers in the surrounding environment (FIG. 4A, FIG. 4B, and FIG. 4C). This ionic dissociation and heterogeneous charge distribution along the radial direction were the main reasons for the electrical generation capability of the fabricated device. According to zeta potential analysis (FIG. 4D), which reflects the surface potential and charge capacity achieved through moisture absorption and ionic dissociation, pure NaAlg and PDDA exhibited negative and positive charges, respectively. After the coacervation of NaAlg and PDDA, the resulting gel showed a positive surface charge. Interestingly, the absolute value of the zeta potential after mixing the two components was higher than that of the individual components, enhancing the MEG performance. As PDDA was added, the particle size of the PDDA/NaAlg mixture decreased from 1100 nm to 450 nm, reaching a minimum of 450 nm for P5N20 (FIG. 4E). These results indicate that the dense coacervation of the two polymer chains within P5N20 created more free space that could facilitate ionic diffusion.

To identify the notable causes of MEG performance, additional investigations were conducted, which included PEDOT electrodes. In KPFM tests, the surface potential of PEDOT exhibited a significantly negative charge of approximately −400 mV, which is a characteristic that differs greatly from traditional metallic materials (FIG. 4F and FIG. 4G). This characteristic appears to enable the MEG to generate an electric field embedded in the radial direction, thereby accelerating ion movement. Various metal fibers were also used as alternatives to the PEDOT core electrode, and their MEG-related performance was evaluated. To test the CV curve of the fiber-type MEG, cyclic voltammetry (CV) techniques were employed. The CV curve did not show a clear oxidation-reduction peak, indicating that the electrochemical reaction contributes minimally to the performance. These results demonstrate that PEDOT significantly enhances both the output voltage and current of the MEG, playing a crucial role in improving performance by enhancing electron and ion transport processes. The inventors also studied the MEG performance of PDDA/NaAlg using a film system with symmetric Ag electrodes or PEDOT electrodes. The results showed that the output performance of the MEG device varied depending on the combination of symmetric inactive electrodes, with the symmetric Ag electrode yielding an open-circuit voltage of approximately 102 mV and a short-circuit current density of 0.2 μA/cm², while the symmetric PEDOT electrode achieved 350 mV and 20 μA/cm². These results differ from those obtained using symmetric Cu electrodes, and the phenomenon of performance variation when changing electrode pairs has been reported in other literature as well. This is related to the unique work function, surface roughness, and defects of the electrode materials, which influence the formation of the electric double layer at the material surface.

In addition, small-angle X-ray scattering (SAXS) analysis was performed to elucidate the role of the interaction between NaAlg and PDDA in enhancing the performance of the moisture electricity generator (MEG) (FIG. 4H and FIG. 4I). The log-log SAXS profile of the NaAlg-based material revealed three important parameters: α2, R1, and α1. These correspond to the density of the rods, the size of the rods, and the fractal dimension of the rod network, respectively. The results showed that as the NaAlg ratio increased, α2 increased and R1 decreased, indicating a reduction in rod size and confirming volume contraction after coacervation. The increase in al suggests the presence of more branched structures within the coacervate gel network, which may generate more micropores and facilitate charge carrier diffusion. Subsequently, coacervate gel fibers with varying NaAlg/PDDA ratios were prepared, and their MEG-related performance was compared. The results indicated that the coacervate gel exhibited significantly superior performance compared to pure NaAlg, with the P5N20 variant achieving an impressive output voltage of up to 0.8V. These findings emphasize the importance of the interaction between NaAlg and PDDA in enhancing MEG efficiency.

The effect of complex coacervation on free ions within the system was tested through X-ray diffraction (XRD) and ionic conductivity analysis. The XRD patterns did not show distinct peaks in samples with different PDDA/NaAlg ratios, indicating the presence of an amorphous structure (FIG. 4J). This structure suggests that there are abundant internal defects that facilitate ion diffusion. Notably, peaks corresponding to NaCl crystals appeared in all coacervate gel profiles, and their intensity slightly increased with the addition of NaAlg. These peaks were not observed in pure NaAlg. These results indicate that complex coacervation can release more free ions (Na and Cl) within the gel, thereby enhancing the MEG performance during moisture absorption. The electrical conductivity test showed that the ionic conductivity of P5N20, which exhibited optimal MEG performance, is ten times that of pure NaAlg, indicating that ion diffusion is significantly rapid. Various beneficial effects of complex coacervation were verified by comparing the MEG-related performance of coacervate gel fibers with different NaAlg/PDDA ratios (FIG. 4L). The results demonstrated that the complex coacervate gel exhibited significantly superior performance compared to pure NaAlg, with the P5N20 variant achieving maximum output voltage and current (FIG. 4L). These findings emphasize that the interaction between NaAlg and PDDA is crucial for enhancing MEG efficiency.

Combining all the characterization results, the mechanism for performance enhancement is well explained. When the fiber-type moisture electricity generator (MEG) absorbs moisture from the air, the complex coacervation of PDDA and NaAlg on the outer surface of the fiber dissociates under the influence of water molecules, resulting in the release of a large number of freely mobile Na+ and Cl− ions. At the same time, the PDDA/NaAlg coacervate generates numerous pores that facilitate ion diffusion. As a result, a concentration gradient of ions and water is formed radially within the fiber. Due to the negatively charged surface of PEDOT, when the external circuit is completed, a built-in potential is established between the electrodes, accelerating the diffusion of Na+ ions from the outer surface inward in a radial direction, while Cl− ions diffuse in the opposite direction. Therefore, the synergistic effect of the complex coacervation of the two polymers and the built-in potential of the electrodes significantly enhances the moisture-driven electricity generation performance.

### Molecular Dynamics Simulation

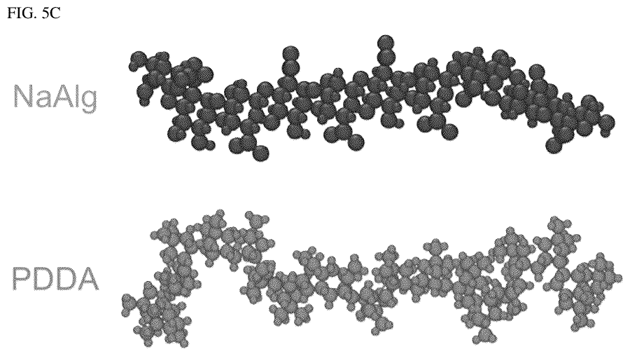

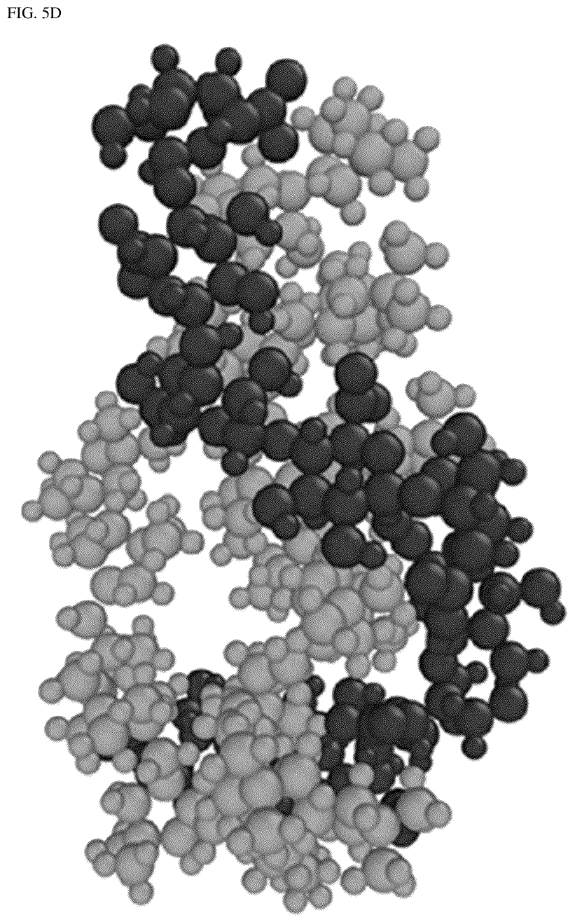

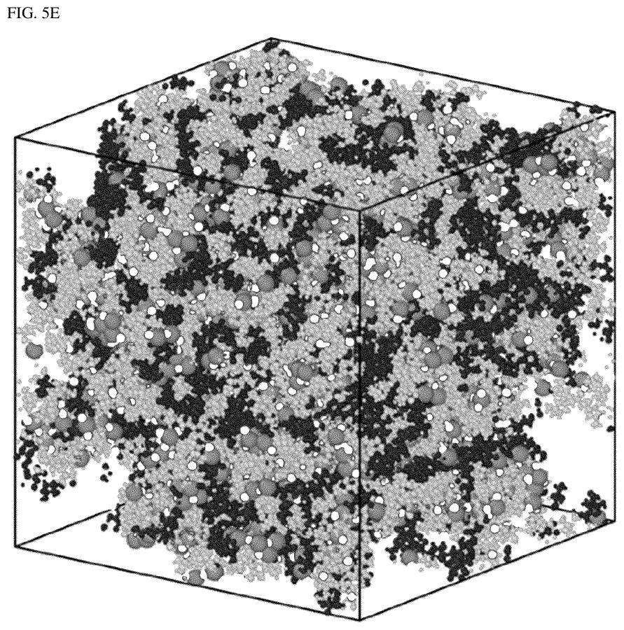

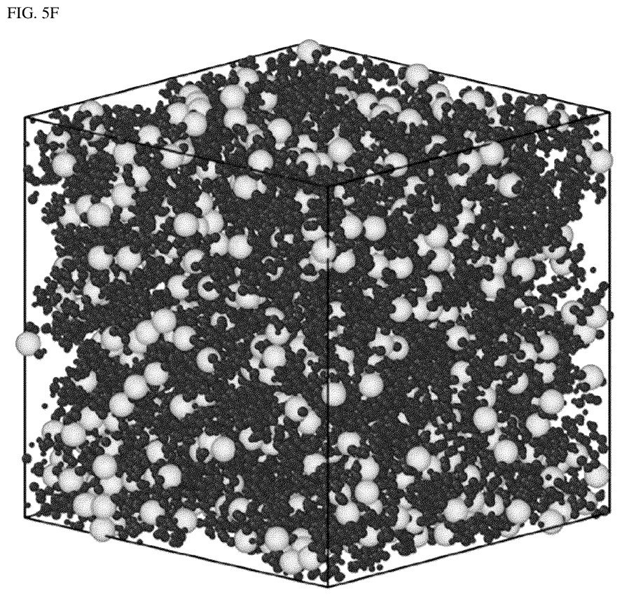

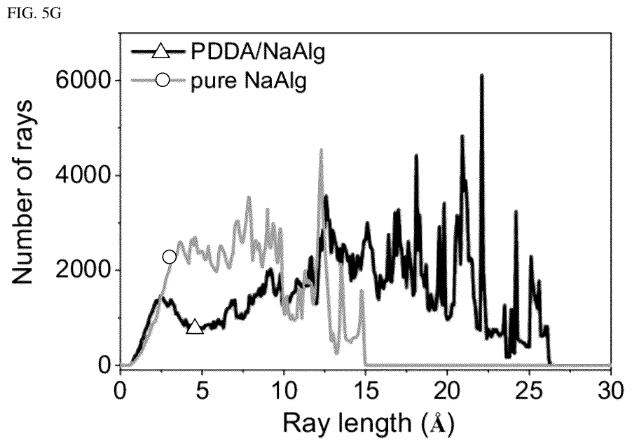

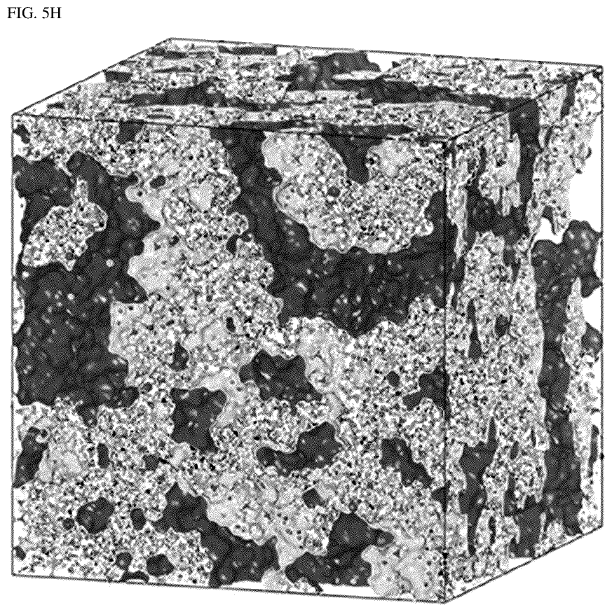

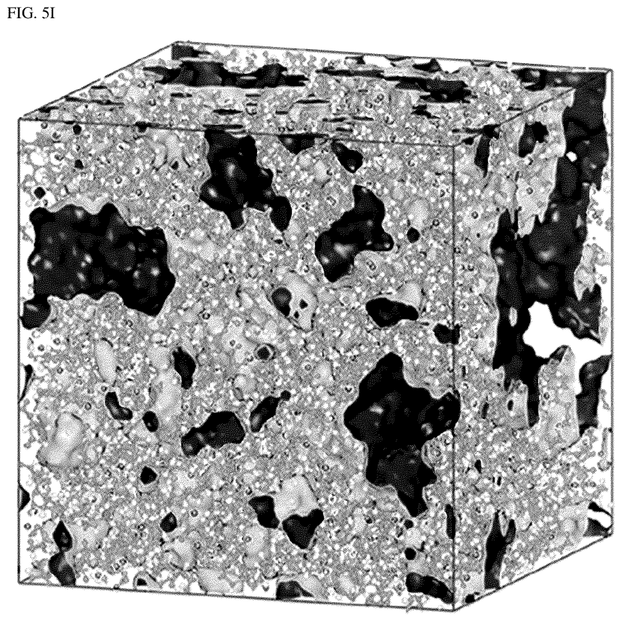

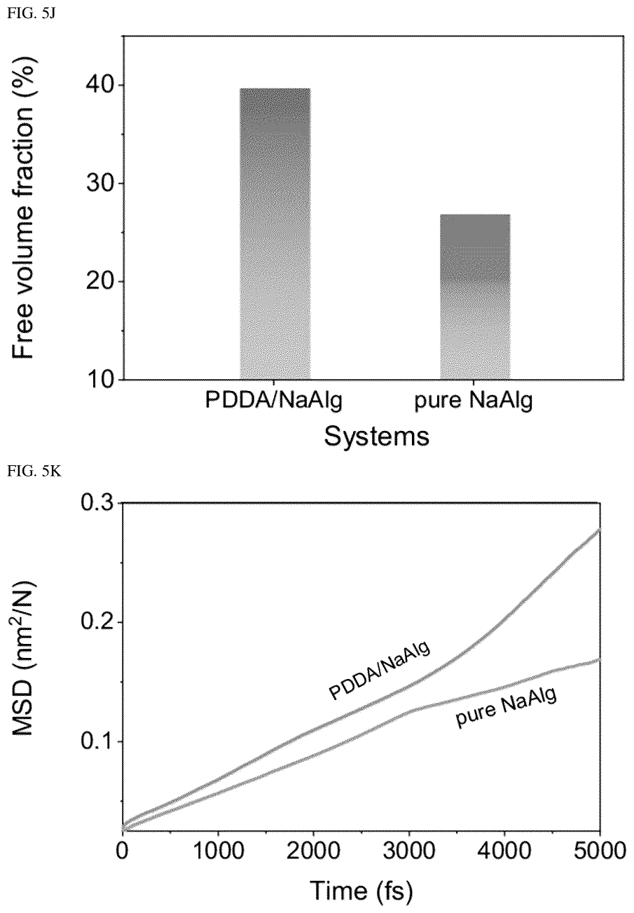

To further explore the interaction between NaAlg and PDDA, simulations were conducted. Initially, surface potentials for the units within the two polyelectrolytes were determined through density functional theory (DFT) calculations (FIG. 5A and FIG. 5B). The results indicated that the —COOH region of NaAlg and the quaternary ammonium salt region of PDDA exhibited the highest surface potentials, confirming the expected sites for complex coacervation. Subsequently, molecular dynamics simulations were performed to investigate the polymer chain interactions within pure NaAlg and the PDDA/NaAlg system (refer to Methods). The equilibrium structures of these systems (FIG. 5E and FIG. 5F) clearly demonstrated that the PDDA/NaAlg system possessed more free space than pure NaAlg. This observation was further corroborated through video recordings. The typical post-assembly structure within the PDDA/NaAlg system exhibited a double helix structure similar to DNA, which starkly contrasted with the irregular polymer chains observed in pure NaAlg and pure PDDA (FIG. 5C and FIG. 5D). To vividly illustrate the free volume, the free volume and polymer chain distribution areas were mapped through simulations (FIG. 5H and FIG. 5I). The PDDA/NaAlg system contained a greater amount of blue regions, indicating larger pore areas, which is consistent with the SAXS results. A more comprehensive comparison was conducted by quantitatively analyzing the pore distribution, free volume ratio, and mean square displacement (MSD) of ions in both systems (FIG. 5G, FIG. 5J, and FIG. 5K). The results showed that the pores in the PDDA/NaAlg system were widely distributed and that larger gaps appeared more frequently (FIG. 5G). Statistical analysis of the free space indicated that the free volume ratio of the PDDA/NaAlg system (40%) was significantly higher than that of NaAlg (26%) (FIG. 5J). The MSD analysis quantified the deviation of particle positions over time relative to a reference position, which is a common measure of spatial range in random motion, representing the portion of the system “explored” by a random walker. The statistical results demonstrated that the MSD of the PDDA/NaAlg system increased 1.65 times faster than that of pure NaAlg. Furthermore, this difference showed a tendency to widen, indicating that random ionic motion or diffusion in the PDDA/NaAlg system is significantly faster. This result aligns with the ionic conductivity test results, suggesting that the ionic diffusion rate is faster within the complex coacervate. All simulation results are consistent with experimental findings, further confirming that the coacervation of NaAlg and PDDA leads to the contraction of the polymer backbone and the formation of more channels, thereby facilitating ionic diffusion and providing high-performance MEG.

To further verify the efficiency and accuracy of the complex coacervation and built-in potential strategies, another complex coacervate gel featuring PEI and PSS films was produced; these components were combined with a PEDOT film and a perforated Cu foil electrode to form the MEG. MEG tests indicated that the PEI/PSS complex coacervate gel film showed significant improvements in both voltage and current compared to pure PEI and PSS films. Specifically, the voltage increased by 100%, and the current level also dramatically increased (by factors of 10 and 100,000, respectively). Subsequently, replacing the PEDOT film electrode with an Au film resulted in the MEG performing worse than the PEDOT-based device, with voltage and current decreasing by factors of two and ten, respectively. These experimental results confirm the effectiveness and versatility of the synergistic complex coacervation and built-in potential strategies in both fiber and film devices.

### Self-Powered Information Exchange]

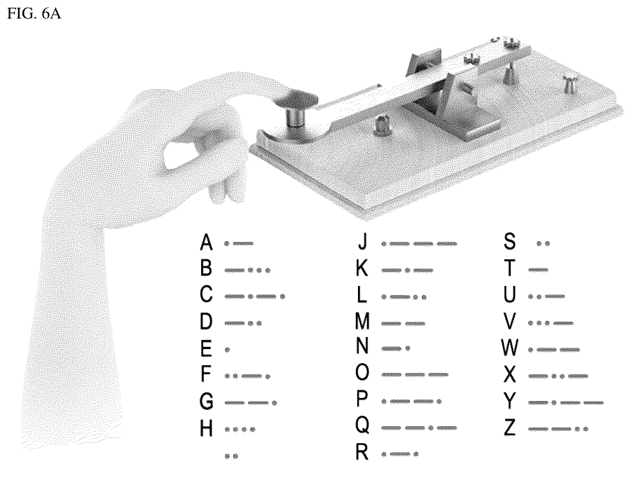

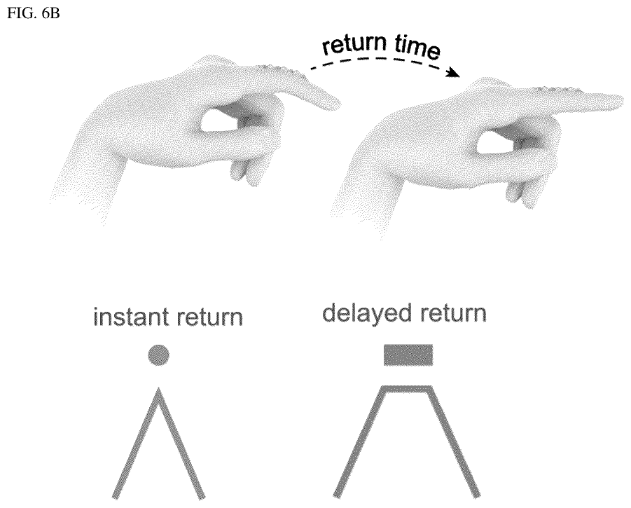

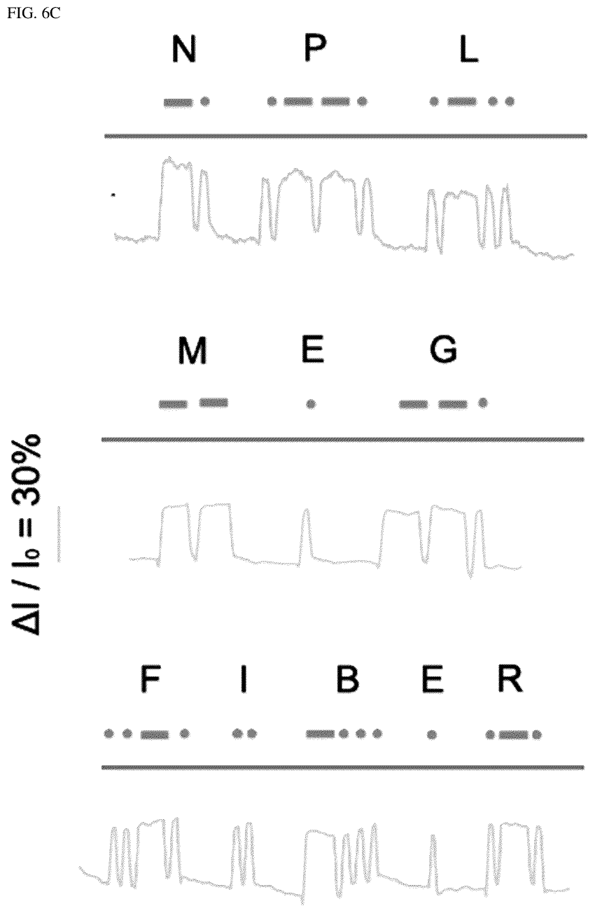

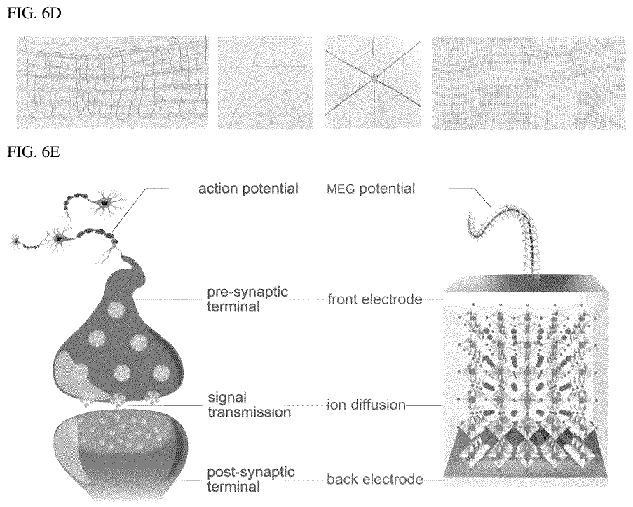

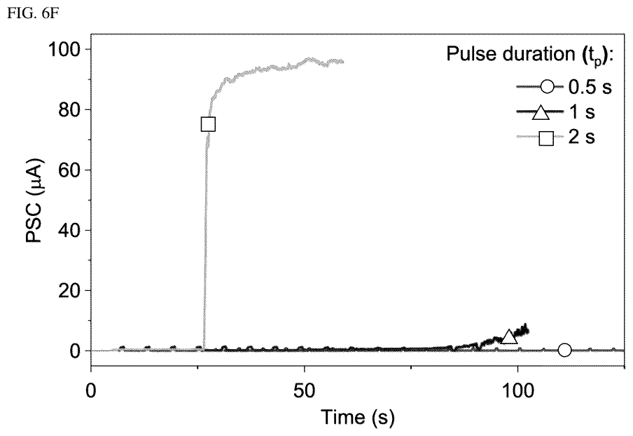

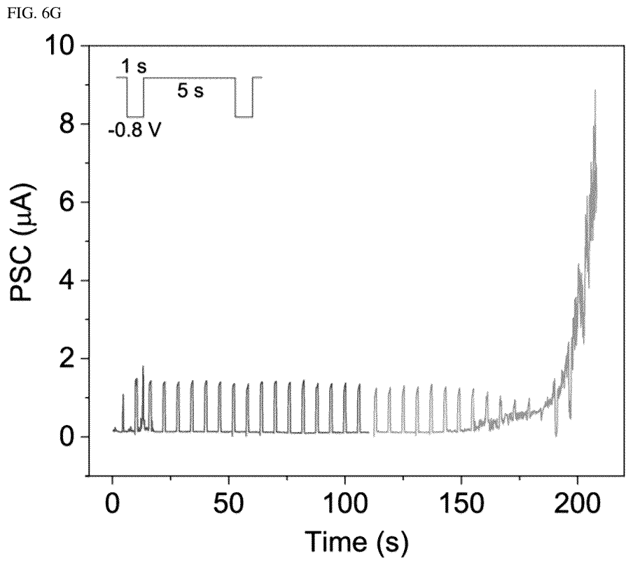

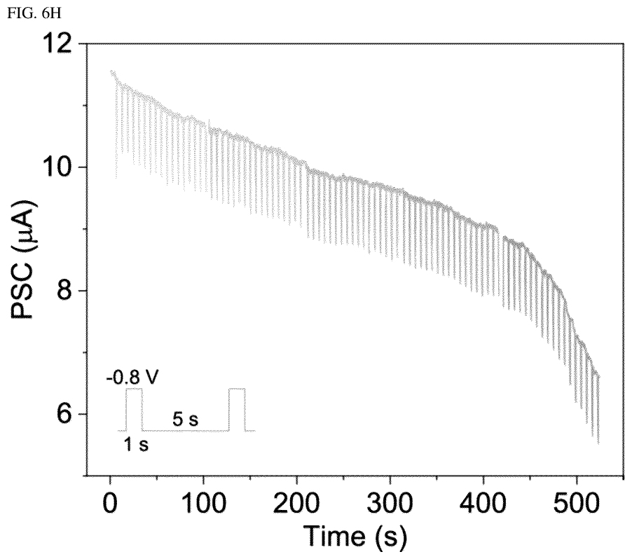

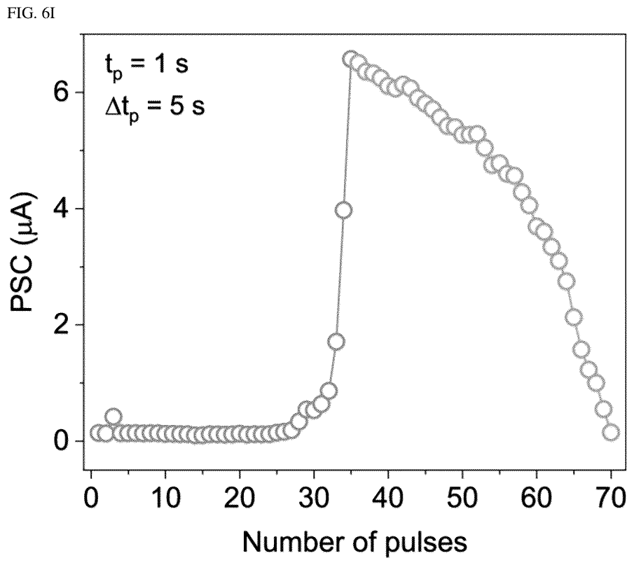

The fiber-based moisture electricity generator (MEG) has been used as a self-powered finger movement sensor that enables information encoding by leveraging excellent flexibility and dynamic bending resolution. The sensor design was inspired by traditional telegraph systems (FIG. 6A). The classical Morse telegraph operates by having the operator manipulate a key to control the interruption of an electric circuit, generating a combination of electrical signals that represent various letters and numbers. The generation of dots and lines constitutes the fundamental mechanism of operation. Inspired by this scheme, the fiber MEG device is designed to be worn on the finger, generating similar dots and lines by controlling the time the finger is bent. When the finger quickly returns to a straight position after bending, a spike in the electrical signal is generated to represent a dot, while a delayed return produces a flat peak that intuitively represents a line (FIG. 6B). In this device, changes in current are used as information transmission signals. This is because bending induces deformation, altering the resistance of the shell and the contact area with the electrodes, resulting in a distinct change in current. By utilizing this principle, electrical signals generated during finger bending were detected to transmit information. The fiber-based MEG device clearly transmitted information in word forms such as “NPL,” “Fiber,” and “MEG” (FIG. 6C). The peaks have distinct and easily distinguishable shapes. More importantly, this device can operate without an external power source. It can function using electrical energy harvested from moisture in the air. This demonstrates the extensive potential of the device in the advanced field of self-powered information exchange.

The above results demonstrate the excellent flexibility of the single fiber; however, additional assembly and integration are important for practical applications. The results of the manual assembly experiments showed that the complex coacervate gel fibers could be woven into various structures or shapes, such as fabrics, pentagram shapes, and spider webs (FIG. 6D). Additionally, the fibers were inserted into the fabric to form various patterns and underwent several reversible deformations. These findings certainly showcase the impressive assembly and integration capabilities of the complex coacervate gel fibers, laying the foundation for large-scale applications. In summary, the fiber-type MEG device significantly enhances flexibility after assembly by using flexible electrodes compared to conventional film-type and 3D structures. Furthermore, the woven structure creates numerous mesh openings, providing the device with excellent breathability, which becomes a unique advantage for wearable devices.

### Self-Powered Synapse Device

To further utilize the long-term operating characteristics of the self-powered fiber-based moisture electricity generator (MEG), this device was used to drive an artificial synapse device by mimicking the action potential of synapses under ambient conditions (FIG. 6E). In biological synapses, action potentials are generated in the presynaptic neuron and transmitted across the synaptic cleft, where neurotransmitters are released from synaptic vesicles into the synaptic cleft. These neurotransmitters are received by receptors on the postsynaptic membrane, generating postsynaptic current (PSC). The magnitude of the PSC is determined by the synaptic weight (w) between the presynaptic and postsynaptic neurons, which facilitates the strengthening or suppression of the synapse depending on the charge ions diffusing across the plasma membrane of the dendrites. In this device, the potential of the fiber MEG can act as the action potential driving the synapse device, with the hole carriers of the perovskite serving as neurotransmitters, and silver and indium tin oxide (ITO) electrodes being used to collect current signals like the two terminals in biological synapses. Therefore, this combination of components can help form the first self-powered MEG-driven artificial synapse device. Various tests were conducted to evaluate the operating conditions of the self-powered synapse. First, the effect of pulse duration on the PSC controlled by a relay connected to the circuit was investigated. According to the results, a pulse duration of 0.5 seconds was sufficient to drive the synapse device with a single MEG unit. Notably, the device achieved higher PSC in a shorter period as the pulse duration increased (FIG. 6F). The long-term neuroplasticity of the device was examined at a pulse duration of 0.5 seconds, which included an analysis of long-term potentiation (LTP) and long-term depression (LTD), key mechanisms governing learning and memory storage in the human brain. The device exhibited good neuroplasticity at high pulse counts, and the growth rate of the PSC was relatively low, highlighting its potential for specific precise applications (FIG. 6G, FIG. 6H, and FIG. 6I). Overall, these results emphasize the prospects of the manufactured MEG for long-term operation of self-powered devices and indicate the successful fabrication of the first MEG-synapse self-powered device.

### CONCLUSION

The present invention has made significant advancements in the field of moisture electricity generators (MEGs) by implementing a synergistic complex coacervation and built-in potential strategy, and by developing a novel PEDOT@PDDA/NaAlg core-shell coacervate gel fiber. The PEDOT@PDDA/NaAlg coacervate gel fiber exhibited excellent performance characteristics, including a maximum output voltage of 0.8V, a current density of 1.05 mA/cm², and a power density of 184 W/cm² at 20% relative humidity (RH), while addressing several issues related to achieving high flexibility. The mechanism for performance enhancement was found to be the complex coacervation of the oppositely charged PDDA and NaAlg polymer electrolytes within the fiber shell, which released a large number of large ions as charge carriers and created large ion diffusion channels. Furthermore, the negative surface potential of the conductive PEDOT core of the fiber facilitated the diffusion of charge carriers, thereby improving the MEG performance. Thanks to the outstanding flexibility and weaving capability of the PEDOT@PDDA/NaAlg fiber, fiber-based MEGs have been successfully utilized in self-powered information transmission devices and artificial synapse devices. Considering the potential for flexible power generation and significant applications in human-machine interactions, the PEDOT@PDDA/NaAlg coacervate gel fiber demonstrates possibilities for advanced applications in various fields.

### Method

### Material

NaAlg, PDDA, calcium chloride, concentrated sulfuric acid, ethanol, and deionized water were purchased from Sigma-Aldrich. The aqueous PEDOT:PSS dispersion (Clevios™ PH 1000; concentration, approximately 1.2%) was obtained from Heraeus Epurio.

### Preparation of PEDOT Ribbons

The spinning composition consists of a 3.5 weight % PEDOT:PSS solution, which was prepared by removing a portion of water from a commercial product at 60° C. Prior to wet spinning, the spinning composition was subjected to ultrasonic treatment for 30 minutes to remove bubbles. The ribbon was prepared using a self-made wet spinning system at room temperature (FIG. 2A). In this process, the spinning composition was filled into a 6 mL syringe and connected to a micro-injection pump, then released into a concentrated H2SO4 coagulation solution at a spinning rate of 2 mL/h through a 23G blunt needle located at the bottom. The resulting PEDOT ribbon passed through a washing bath containing a 3:1 ethanol/water mixture to remove any remaining H2SO4. After drying, the PEDOT ribbon was wound onto a spool.

### Preparation of PEDOT@PDDA/NaAlg Coacervate Gel Fibers

The general procedure for manufacturing core-shell type PEDOT@PDDA/NaAlg coacervate gel fibers is as follows. First, a 1 weight % aqueous NaAlg solution is prepared, and various volumes of this solution are mixed with a 35 weight % aqueous PDDA solution to create a precursor mixture for coacervate gel formation. The mixing ratio is denoted as PxNy, where x and y represent the volumes of PDDA and NaAlg, respectively. Next, the ribbon is sequentially immersed in a 20 weight % CaCl₂) solution, the PxNy coacervate gel precursor solution, and another 20 weight % CaCl₂) solution to form an outer coacervate gel layer through ion-induced gelation. Subsequently, core-shell type PEDOT@PxSy coacervate gel fibers are obtained and dried under ambient conditions. The coacervate gel fibers are wrapped in thin copper for additional testing, and a super flexible fiber-based MEG device is assembled.

### Characterization Method

The morphology and microstructure were investigated using a field emission scanning electron microscope (FE-SEM; JEOL, 7001F). The elemental composition and distribution of the sample were analyzed using an EDS device attached to the FE-SEM equipment. The chemical elements and bonding states were examined using X-ray photoelectron spectroscopy (XPS) with a K-Alpha spectrometer (Thermo Scientific, USA). The crystal structure of the sample was analyzed using X-ray diffraction (XRD) with a Bruker D8 Focus diffractometer under conditions of Cu Kα radiation (λ=0.15418 nm), 40 kV, and 40 mA. FT-IR spectra were obtained using a Bruker VERTEX 70 FT-IR spectrometer. SAXS data were collected at the PLS-II 9A U-SAXS beamline of the Pohang Accelerator Laboratory. The contact angle was measured using an optical contact angle goniometer (KRUSS DSA 100, Germany). The zeta potential was measured using the ELS-1000ZS device (Otsuka Electronics). KPFM was performed using a Multimode 8 device (TECSCO). Electrochemical impedance spectroscopy (EIS) curves were obtained using an electrochemical workstation (VMP3, Princeton Applied Research). The open-circuit voltage (Voc) and short-circuit current (Jsc) of the MEG were measured using a Keithley 6514 electrometer and a Keithley 6485 picoammeter. When calculating the current density of the fiber, the surface area of the fiber in a fully extended state was used as the basis for calculation according to the generation principle. Relative humidity (RH) control was achieved using a humidity chamber within an acrylic case that included a humidifier and humidity sensor. Experiments were conducted at temperatures between 20° C. and 120° C. using a heating plate. The flexibility of the fiber-based MEG device was characterized in three dimensions through rotation, twisting, and bending. In the bending test, the fiber-based MEG was attached to a PET substrate and affixed to a folding device that assisted in examining the MEG performance under various bending angles and folding repetitions.

### Fabrication and Testing of a Self-Powered Synapse Device

The device has a sandwich structure and includes ITO and Ag as the lower and upper electrodes, respectively. At the center of this structure, a 2D chiral perovskite layer positioned between the two electrodes acts as the active layer. The composition of the active layer is noteworthy in that it contains enantiomers such as (R)-(+)-α-methylbenzylamine (R-MBA) and (S)-(−)-α-methylbenzylamine (S-MBA) as organic components. These are combined with a mixture of iodide and bromide halides along with the metal element Pb. The resulting active layer chemical compound (R/S-(MBA)2PbI4(1-x)Br4x) is integrated into a 4×4 crossbar array device. Each unit of this device is connected to individual fiber-based MEG units using gold wires. This configuration leads to a 4×4 self-powered synapse device (FIG. 6F).

### Molecular Dynamics Simulation

Classical molecular dynamics simulations were conducted to explore the mixed systems at the atomic level. Two separate bulk systems, distinguished as PDDA/NaAlg and pure NaAlg, were constructed for these simulations. The PDDA/NaAlg system consists of 100 ALGI, 100 PDDA, 1000 Na, and 2000 Cl molecules, while the pure NaAlg is composed of 100 ALGI and 1000 Na molecules. The initial configurations of the two systems were generated using PACKMOL software. The partial charges of the target molecules were calculated using Gaussian 16 software with the 6-311g(d,p) basis set. The interactions among ALGI, PDDA, Na, and Cl were modeled using the OPLSAA force field, which includes both non-bonded and bonded interactions. The latter includes van der Waals (vdW) and electrostatic components, expressed by their respective equations:

$${E}_{LJ} ( {r}_{ij} ) = 4 {ε}_{ij} ( {( \frac{{σ}_{ij}}{{r}_{ij}} )}^{12} - {( \frac{{σ}_{ij}}{{r}_{ij}} )}^{6} ) \qquad ( 1 )$$

$${E}_{c} ( {r}_{ij} ) = \frac{{q}_{i} {q}_{j}}{4 {πε}_{0} {ε}_{r} {r}_{ij}} \qquad ( 2 )$$

wherein qᵢ and qⱼ represent the atomic charges, rᵢⱼ is the interatomic distance, σ is the atomic diameter, and ϵ is the atomic energy parameter. The van der Waals (vdW) interactions were calculated by applying geometric mixing rules for various types of atoms (Equation (3)). The cutoff for vdW and electrostatic interactions was set to 1.2 nm. Long-range electrostatic interactions were calculated using the particle-mesh Ewald method.

$${σ}_{ij} = {( {σ}_{ii} {σ}_{jj} )}^{1 / 2} ; {ε}_{ij} = {( {ε}_{ii} {ε}_{jj} )}^{1 / 2} \qquad ( 3 )$$

The simulation began with an energy minimization step to stabilize the system. Subsequently, an isothermal-isobaric (NPT) ensemble was implemented with a time interval of 1.0 fs to optimize the simulation box, maintaining the temperature and pressure at 298.15 K and 1.0 atm, respectively. The temperature and pressure were stabilized using the Nose-Hoover thermostat and the Parrinello-Rahman barostat, respectively. A stable box size was achieved over a 10.0 ns NPT optimization period. In all simulations, the motion of the atoms was governed by classical Newtonian mechanics and was solved using the velocity Verlet algorithm. These simulations were performed using the GROMACS 2021.5 package. The pore size distribution analysis was conducted using Zeo++.

Although the above has been described with reference to preferred embodiments of the present invention, those skilled in the art will understand that various modifications and changes can be made to the present invention without departing from the spirit and scope of the invention as set forth in the following patent claims.

What is claimed is:

1. A moisture electricity generator comprising:
a core including a conductive polymer; and
a shell that at least partially surrounds the core and includes a complex coacervate containing ions,
wherein a potential gradient is generated from a difference in moisture or wettability between the core and the shell.

2. The moisture electricity generator of claim 1,
wherein the conductive polymer comprises poly(3,4-ethylenedioxythiophene) (PEDOT).

3. The moisture electricity generator of claim 1,
wherein the complex coacervate comprises polydiallyldimethylammonium chloride (PDDA) and sodium alginate (NaAlg).

4. The moisture electricity generator of claim 1,
further comprising a peripheral electrode formed on an outer surface of the shell,
wherein the moisture electricity generator generates electrical energy from the potential gradient between the core and the peripheral electrode.

5. The moisture electricity generator of claim 4,
wherein the peripheral electrode comprises a metal.

6. The moisture electricity generator of claim 1,
wherein the core and the shell are formed in a fiber form.

7. The moisture electricity generator of claim 6,
further comprising a peripheral electrode formed on an outer surface of the shell,
wherein the peripheral electrode is formed of a metal wire spirally wound around the fibrous core and shell,
and wherein the moisture electricity generator generates electrical energy from the potential gradient between the core and the peripheral electrode.

8. A method of manufacturing a moisture electricity generator, comprising:
forming a shell that at least partially surrounds a core including a conductive polymer, the shell including a complex coacervate containing ions.

9. The method of claim 8,
wherein the conductive polymer comprises poly(3,4-ethylenedioxythiophene) (PEDOT).

10. The method of claim 8,
wherein the complex coacervate comprises polydiallyldimethylammonium chloride (PDDA) and sodium alginate (NaAlg).

11. The method of claim 8,
further comprising forming a peripheral electrode on an outer surface of the shell.

12. The method of claim 11,
wherein the peripheral electrode comprises a metal.

13. The method of claim 8,
wherein the core is prepared in a fiber form, and
the shell is formed in a fiber form surrounding the core.

14. The method of claim 13,
further comprising forming a peripheral electrode on an outer surface of the shell,
wherein the peripheral electrode is formed by spirally winding a metal wire around the fibrous core and shell.

15. An electricity generator, comprising the moisture electricity generator according to claim 1,
connected to a self-powered sensor or an artificial synapse device.
